(19) United States
(12) Patent Application Publication
(10) Pub. No.: US 2026/0136756 A1
(43) Pub. Date: May 14, 2026

(54) Light-Emitting Device

(71) Applicant: Semiconductor Energy Laboratory Co., Ltd., Kanagawa-ken (JP)

(72) Inventors: Hiromitsu KIDO, Atsugi (JP); Nobuharu OHSAWA, Zama (JP); Takeyoshi WATABE, Atsugi (JP)

(73) Assignee: Semiconductor Energy Laboratory Co., Ltd., Kanagawa-ken (JP)

(21) Appl. No.: 19/380,467

(22) Filed: Nov. 5, 2025

(30) Foreign Application Priority Data
Nov. 8, 2024 (JP) 2024-196216
May 2, 2025 (JP) 2025-076742

(51) Int. Cl. H10K 50/16; H10K 50/15; H10K 101/00

(52) U.S. Cl. CPC H10K 50/166; H10K 50/15; H10K 2101/80

(57) ABSTRACT

A light-emitting device having high reliability is provided. A light-emitting device is provided, which includes a first electrode formed over an insulating surface, a second electrode facing the first electrode, and an EL layer positioned between the first electrode and the second electrode. One of the first and second electrodes is an anode, and the other is a cathode. The EL layer includes a light-emitting layer, a first layer, and a second layer. The first and second layers are positioned between the light-emitting layer and the cathode. The first layer is positioned between the first electrode and the second layer. The second layer is positioned between the first layer and the second electrode. The GSP_Slope (mV/nm) of the second layer is larger than the GSP_Slope (mV/nm) of the first layer (note that the GSP_Slope (mV/nm) is represented by ΔV/Δd where ΔV (mV) is the amount of change in surface potential and Δd (nm) is the amount of change in thickness).

### BACKGROUND OF THE INVENTION

### 1. Field of the Invention

One embodiment of the present invention relates to an organic compound, an organic semiconductor element, a light-emitting element, an organic EL element, a photodiode, a display module, a lighting module, a display device, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Light-emitting devices (organic EL elements) including organic compounds and utilizing electroluminescence (EL) have been put into practical use. In the basic structure of such organic EL elements, an organic compound layer containing a light-emitting material (an EL layer) is located between a pair of electrodes. Carriers are injected by application of voltage to the device, and recombination energy of the carriers is used, whereby light emission can be obtained from the light-emitting material.

Such organic EL elements are of self-luminous type and thus have advantages over liquid crystal elements, such as high visibility and no need for backlight when used as pixels of a display, and are particularly suitable for flat panel displays. Displays including such organic EL elements are also highly advantageous in that they can be thin and lightweight. Another feature of such organic EL elements is that they have an extremely fast response speed.

Since light-emitting layers of such organic EL elements can be formed as continuous planar layers, planar light emission can be achieved. This feature is difficult to realize with point light sources typified by incandescent lamps and LEDs or linear light sources typified by fluorescent lamps; thus, the organic EL elements also have great potential as planar light sources, which can be used for lighting devices and the like.

Displays or lighting devices that include organic EL elements are suitable for a variety of electronic appliances as described above, and research and development of organic EL elements have progressed for better characteristics.

[Reference]

### Non-Patent Document

[Non-Patent Document 1] Y. Noguchi et al., “Spontaneous Orientation Polarization of Polar Molecules and Interface Properties of Organic Electronic Devices”, Journal of the Vacuum Society of Japan, 2015, Vol. 58, No. 3

### SUMMARY OF THE INVENTION

An object of one embodiment of the present invention is to provide a light-emitting device having high reliability. Another object of one embodiment of the present invention is to provide a light-emitting device having high emission efficiency. Another object of one embodiment of the present invention is to provide a light-emitting device having a low driving voltage. Another object of one embodiment of the present invention is to provide any of a light-emitting apparatus, an electronic appliance, and a display device each having high reliability.

Another object of one embodiment of the present invention is to provide a blue phosphorescent light-emitting device having high reliability. Another object of one embodiment of the present invention is to provide a blue phosphorescent light-emitting device having high emission efficiency. Another object of one embodiment of the present invention is to provide a blue phosphorescent light-emitting device having a low driving voltage.

Note that the description of these objects does not preclude the existence of other objects. One embodiment of the present invention does not need to achieve all of these objects. Other objects will be apparent from and can be derived from the description of the specification, the drawings, the claims, and the like.

One embodiment of the present invention is a light-emitting device including a first electrode formed over an insulating surface, a second electrode facing the first electrode, and an EL layer positioned between the first electrode and the second electrode; the EL layer includes a light-emitting layer, a hole-transport layer, a first electron-transport layer, and a second electron-transport layer; the first electron-transport layer is positioned between the first electrode and the second electron-transport layer; the light-emitting layer is positioned between the hole-transport layer and the first and second electron-transport layers; and a GSP_Slope (mV/nm) of the second electron-transport layer is larger than a GSP_Slope (mV/nm) of the first electron-transport layer.

Another embodiment of the present invention is a light-emitting device including a first electrode formed over an insulating surface, a second electrode facing the first electrode, and an EL layer positioned between the first electrode and the second electrode; the EL layer includes a light-emitting layer, a hole-transport layer, a first electron-transport layer, and a second electron-transport layer; the first electron-transport layer is positioned between the first electrode and the second electron-transport layer; the light-emitting layer is positioned between the hole-transport layer and the first and second electron-transport layers; the first electron-transport layer contains a first organic compound; the second electron-transport layer contains a second organic compound; the first organic compound and the second organic compound have a π-electron deficient heteroaromatic ring; and a GSP_Slope (mV/nm) of an evaporated film of the second organic compound is larger than a GSP_Slope (mV/nm) of an evaporated film of the first organic compound.

Another embodiment of the present invention is a light-emitting device including a first electrode formed over an insulating surface, a second electrode facing the first electrode, and an EL layer positioned between the first electrode and the second electrode; the EL layer includes a light-emitting layer, a hole-transport layer, a first electron-transport layer, and a second electron-transport layer; the first electron-transport layer is positioned between the light-emitting layer and the second electron-transport layer; the second electron-transport layer is positioned between the first electron-transport layer and the second electrode; the light-emitting layer is positioned between the hole-transport layer and the first electron-transport layer; the first electron-transport layer contains a first organic compound; the second electron-transport layer contains a second organic compound and a first substance; the first organic compound and the second organic compound have a π-electron deficient heteroaromatic ring; and a GSP_Slope (mV/nm) of an evaporated film of the second organic compound is larger than a GSP_Slope (mV/nm) of an evaporated film of the first organic compound.

Another embodiment of the present invention is a light-emitting device including a first electrode formed over an insulating surface, a second electrode facing the first electrode, and an EL layer positioned between the first electrode and the second electrode; the EL layer includes a light-emitting layer, a hole-transport layer, a first electron-transport layer, and a second electron-transport layer; the first electron-transport layer is positioned between the light-emitting layer and the second electron-transport layer; the second electron-transport layer is positioned between the first electron-transport layer and the second electrode; the light-emitting layer is positioned between the hole-transport layer and the first electron-transport layer; the first electron-transport layer contains a first organic compound; the second electron-transport layer contains a second organic compound and a first substance; the first organic compound and the second organic compound have a π-electron deficient heteroaromatic ring; and in a case where a mixing ratio of the second organic compound to the first substance in the second electron-transport layer is x:y, a GSP_Slope (mV/nm) of an evaporated film of the second organic compound is larger than (x+y)/x times a GSP_Slope (mV/nm) of an evaporated film of the first organic compound.

Another embodiment of the present invention is the light-emitting device having the above structure, in which y is greater than or equal to x.

Another embodiment of the present invention is the light-emitting device having the above structure, in which the light-emitting layer contains a substance capable of emitting phosphorescent light.

Another embodiment of the present invention is the light-emitting device having the above structure, in which the substance capable of emitting phosphorescent light emits light when a voltage is applied between the first electrode and the second electrode.

Another embodiment of the present invention is the light-emitting device having the above structure, in which the second electron-transport layer is positioned between the first electron-transport layer and the second electrode, and a GSP_Slope (mV/nm) of the light-emitting layer is larger than the GSP_Slope (mV/nm) of the first electron-transport layer.

Another embodiment of the present invention is the light-emitting device having the above structure, in which the GSP_Slope (mV/nm) of the light-emitting layer is larger than a GSP_Slope (m V/nm) of the hole-transport layer.

Another embodiment of the present invention is the light-emitting device having the above structure, in which the second electron-transport layer is positioned between the first electron-transport layer and the second electrode, the light-emitting layer contains a host material and a light-emitting substance, and a GSP_Slope (mV/nm) of an evaporated film of the host material is larger than the GSP_Slope (mV/nm) of the evaporated film of the first organic compound.

Another embodiment of the present invention is the light-emitting device having the above structure, in which the GSP_Slope (mV/nm) of the evaporated film of the second organic compound is larger than the GSP_Slope (mV/nm) of the evaporated film of the host material.

Another embodiment of the present invention is the light-emitting device having the above structure, in which the hole-transport layer contains a third organic compound, and a GSP_Slope (mV/nm) of the light-emitting layer is larger than or equal to a GSP_Slope (mV/nm) of an evaporated film of the third organic compound.

Another embodiment of the present invention is the light-emitting device having the above structure, in which the hole-transport layer contains a third organic compound, and the GSP_Slope (mV/nm) of the evaporated film of the host material is larger than or equal to a GSP_Slope (mV/nm) of an evaporated film of the third organic compound.

Another embodiment of the present invention is the light-emitting device having the above structure, in which the host material contains a first material and a second material, and the first material and the second material are a combination of organic compounds that form an exciplex.

Another embodiment of the present invention is the light-emitting device having the above structure, in which the first material is an organic compound having a π-electron deficient heteroaromatic ring, and the second material is an organic compound having a π-electron rich heteroaromatic ring or an aromatic amine.

Another embodiment of the present invention is the light-emitting device having the above structure, in which the first substance is a metal complex.

Another embodiment of the present invention is the light-emitting device having the above structure, in which the metal complex is an organic complex including an alkali metal.

Another embodiment of the present invention is the light-emitting device having the above structure, in which a peak wavelength of an emission spectrum of the substance capable of emitting phosphorescent light is greater than or equal to 450 nm and less than or equal to 520 nm.

Another embodiment of the present invention is the light-emitting device having the above structure, in which a peak wavelength of an emission spectrum of the light-emitting substance is greater than or equal to 450 nm and less than or equal to 520 nm.

Note that, in the above embodiment of the present invention, the GSP_Slope (mV/nm) is represented by ΔV/Δd where ΔV (mV) is an amount of change in surface potential and Δd (nm) is an amount of change in thickness.

One embodiment of the present invention can provide a light-emitting device having high reliability. Another embodiment of the present invention can provide a light-emitting device having high emission efficiency. Another embodiment of the present invention can provide a light-emitting device having a low driving voltage. Another embodiment of the present invention can provide any of a light-emitting apparatus, an electronic appliance, and a display device each having high reliability.

Another embodiment of the present invention can provide a blue phosphorescent light-emitting device having high reliability. Another embodiment of the present invention can provide a blue phosphorescent light-emitting device having high emission efficiency. Another embodiment of the present invention can provide a blue phosphorescent light-emitting device having a low driving voltage.

Note that the description of these effects does not preclude the existence of other effects. One embodiment of the present invention does not need to have all of these effects. Other effects will be apparent from and can be derived from the description of the specification, the drawings, the claims, and the like.

### BRIEF DESCRIPTION OF THE DRAWINGS

FIGS. 1A and 1B illustrate structures of light-emitting devices of an embodiment.

FIGS. 2A and 2B illustrate the structures of the light-emitting devices of the embodiment.

FIG. 3 shows capacitance-voltage characteristics of a measurement device 1.

FIG. 4 shows current density-voltage characteristics of the measurement device 1.

FIGS. 5A and 5B illustrate structures of light-emitting devices of an embodiment.

FIGS. 6A and 6B are a top view and a cross-sectional view of a light-emitting apparatus.

FIGS. 7A and 7B are perspective views illustrating a structure example of a display module.

FIGS. 8A and 8B are cross-sectional views illustrating structure examples of display devices.

FIG. 9 is a perspective view illustrating a structure example of a display device.

FIG. 10 is a cross-sectional view illustrating a structure example of a display device.

FIG. 11 is a cross-sectional view illustrating a structure example of a display device.

FIG. 12 is a cross-sectional view illustrating a structure example of a display device.

FIGS. 13A to 13D illustrate examples of electronic appliances.

FIGS. 14A to 14F illustrate examples of electronic appliances.

FIGS. 15A to 15G illustrate examples of electronic appliances.

FIG. 16 shows luminance-current density characteristics of a light-emitting device 1-1, a light-emitting device 1-2, and a light-emitting device 1-3.

FIG. 17 shows luminance-voltage characteristics of the light-emitting device 1-1, the light-emitting device 1-2, and the light-emitting device 1-3.

FIG. 18 shows current efficiency-current density characteristics of the light-emitting device 1-1, the light-emitting device 1-2, and the light-emitting device 1-3.

FIG. 19 shows current density-voltage characteristics of the light-emitting device 1-1, the light-emitting device 1-2, and the light-emitting device 1-3.

FIG. 20 shows blue index-current density characteristics of the light-emitting device 1-1, the light-emitting device 1-2, and the light-emitting device 1-3.

FIG. 21 shows external quantum efficiency-current density characteristics of the light-emitting device 1-1, the light-emitting device 1-2, and the light-emitting device 1-3.

FIG. 22 shows electroluminescence spectra of the light-emitting device 1-1, the light-emitting device 1-2, and the light-emitting device 1-3.

FIG. 23 shows the chromaticity diagram of the light-emitting device 1-1, the light-emitting device 1-2, and the light-emitting device 1-3.

FIG. 24 shows the time dependence of normalized luminances of the light-emitting device 1-1, the light-emitting device 1-2, and the light-emitting device 1-3.

FIG. 25 shows the time dependence of voltages of the light-emitting device 1-1, the light-emitting device 1-2, and the light-emitting device 1-3.

FIG. 26 shows luminance-current density characteristics of a light-emitting device 2-1a, a light-emitting device 2-1b, a light-emitting device 2-2a, a light-emitting device 2-2b, a comparative light-emitting device 2-1, a comparative light-emitting device 2-2a, and a comparative light-emitting device 2-2b.

FIG. 27 shows luminance-voltage characteristics of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIG. 28 shows current efficiency-current density characteristics of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIG. 29 shows current density-voltage characteristics of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIG. 30 shows blue index-current density characteristics of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIG. 31 shows external quantum efficiency-current density characteristics of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIG. 32 shows electroluminescence spectra of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIG. 33 shows the time dependence of normalized luminances of the light-emitting device 2-1a, the light-emitting device 2-1b, the light-emitting device 2-2a, the light-emitting device 2-2b, the comparative light-emitting device 2-1, the comparative light-emitting device 2-2a, and the comparative light-emitting device 2-2b.

FIGS. 34A and 34B show capacitance-voltage characteristics of a light-emitting device 2 and a comparative light-emitting device 2.

FIG. 35 shows luminance-current density characteristics of a light-emitting device 3 and a comparative light-emitting device 3.

FIG. 36 shows current efficiency-current density characteristics of the light-emitting device 3 and the comparative light-emitting device 3.

FIG. 37 shows luminance-voltage characteristics of the light-emitting device 3 and the comparative light-emitting device 3.

FIG. 38 shows current density-voltage characteristics of the light-emitting device 3 and the comparative light-emitting device 3.

FIG. 39 shows blue index-current density characteristics of the light-emitting device 3 and the comparative light-emitting device 3.

FIG. 40 shows external quantum efficiency-current density characteristics of the light-emitting device 3 and the comparative light-emitting device 3.

FIG. 41 shows electroluminescence spectra of the light-emitting device 3 and the comparative light-emitting device 3.

FIG. 42 shows the chromaticity diagram of the light-emitting device 3 and the comparative light-emitting device 3.

FIG. 43 shows the time dependence of normalized luminances of the light-emitting device 3 and the comparative light-emitting device 3.

FIG. 44 shows emission spectra of a film of SiTrzCz2 and a film of PSiCzCz and a PL spectrum of a mixed film of SiTrzCz2 and PSiCzCz at a weight ratio of 1:1.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the position, size, range, or the like of each component illustrated in drawings does not represent the actual position, size, range, or the like in some cases for easy understanding. Therefore, the disclosed invention is not necessarily limited to the position, size, range, or the like disclosed in the drawings and the like.

Ordinal numbers such as “first” and “second” in this specification and the like are used for convenience and do not limit the number or the order of components. The order of components includes, for example, the order of steps or the stacking order of layers. That is, the ordinal numbers used in embodiments of this specification are not necessarily the same as the ordinal numbers used in the claims in some cases. In addition, the ordinal numbers used in examples of this specification are not necessarily the same as the ordinal numbers used in the claims in some cases. Furthermore, the ordinal numbers used in embodiments of this specification are not necessarily the same as the ordinal numbers used in examples of this specification in some cases.

In the description of structures of the present invention in this specification and the like with reference to the drawings, the same components in different drawings are denoted by the same reference numeral in some cases.

In this specification and the like, the term “film” and the term “layer” can be interchanged with each other. For example, the term “conductive layer” can be changed to the term “conductive film” in some cases. Alternatively, for example, the term “insulating film” can be changed to the term “insulating layer” in some cases

Note that in this specification and the like, a photoluminescence (PL) spectrum refers to a spectrum obtained by separating light emitted from a sample irradiated with excitation light into different wavelengths and measuring the emission intensity distribution of each wavelength while an excitation wavelength of excitation light is fixed in fluorometry. Such a spectrum is also referred to as an emission spectrum in some cases. Note that an emission spectrum may include a fluorescence component and a phosphorescence component. In this specification and the like, an emission spectrum including a fluorescence component is particularly referred to as a fluorescence spectrum, and an emission spectrum including a phosphorescence component is particularly referred to as a phosphorescence spectrum in some cases.

### Embodiment 1

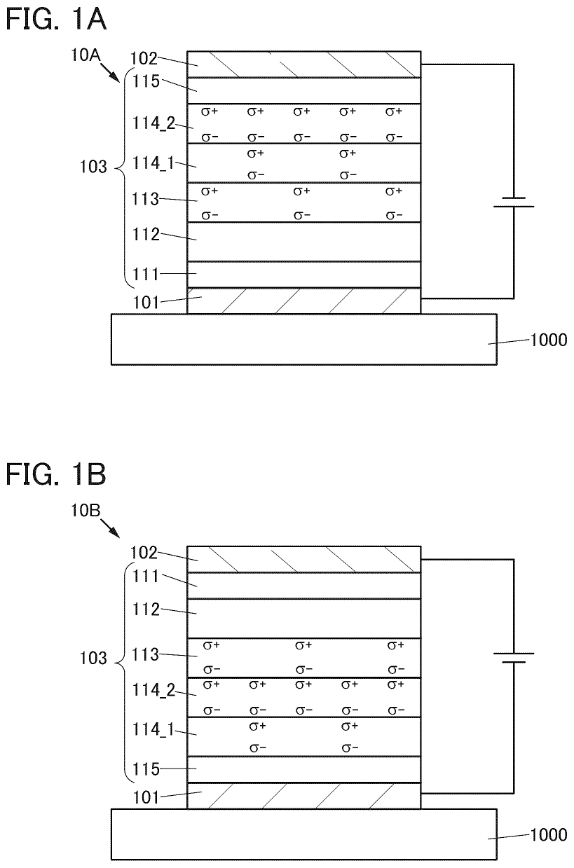

In this embodiment, a light-emitting device 10A and a light-emitting device 10B each of which is a light-emitting device of one embodiment of the present invention are described with reference to FIGS. 1A and 1B.

As illustrated in FIGS. 1A and 1B, the light-emitting devices 10A and 10B are each positioned over a substrate 1000. The light-emitting devices 10A and 10B each include a first electrode 101, a second electrode 102, and an EL layer 103 positioned between the first electrode 101 and the second electrode 102. As illustrated in FIGS. 1A and 1B, the EL layer 103 includes at least a light-emitting layer 113, a first electron-transport layer 114_1, and a second electron-transport layer 114_2. The first and second electron-transport layers 114_1 and 114_2 have a function of transporting electrons, which are injected from either the first electrode 101 or the second electrode 102 to the EL layer 103, to the light-emitting layer 113. Note that the first electron-transport layer 114_1 is positioned between the first electrode 101 and the second electron-transport layer 114_2.

As illustrated in FIGS. 1A and 1B, the first electrode 101 of each of the light-emitting devices 10A and 10B is formed over the substrate 1000. In other words, the first electrode 101 is provided between the second electrode 102 and the substrate 1000. That is, the first electrode 101 is provided earlier than the second electrode 102. Note that in the case where the substrate 1000 is provided with a transistor, the first electrode 101 is electrically connected to the transistor through a wiring. Alternatively, the first electrode 101 is provided over an insulating layer provided with an external connection electrode used as, for example, a terminal to which a flexible printed circuit (FPC) or the like is attached. Alternatively, the end portion of the first electrode 101 is covered with an insulating film.

The light-emitting device 10A illustrated in FIG. 1A and the light-emitting device 10B illustrated in FIG. 1B differ in the functions of the first electrode 101 and the second electrode 102. In the light-emitting device 10A, the first electrode 101 and the second electrode 102 function as an anode and a cathode, respectively. In this specification and the like, in some cases, a light-emitting device like the light-emitting device 10A in which a first electrode on the substrate side functions as an anode is referred to as an ordered stacked light-emitting device. Meanwhile, in the light-emitting device 10B, the first electrode 101 and the second electrode 102 function as a cathode and an anode, respectively. In this specification and the like, in some cases, a light-emitting device like the light-emitting device 10B in which a first electrode on the substrate side functions as a cathode is referred to as an inverted stacked light-emitting device.

The ordered stacked light-emitting device 10A emits light when holes injected from the first electrode 101 functioning as an anode into the EL layer 103 and transported by a hole-transport layer 112 and electrons injected from the second electrode 102 functioning as a cathode into the EL layer 103 and transported by an electron-transport layer 114 are recombined in the light-emitting layer 113. Thus, in the light-emitting device 10A, the hole-transport layer 112 is positioned between the first electrode 101 and the light-emitting layer 113, and the electron-transport layer 114 is positioned between the second electrode 102 and the light-emitting layer 113.

The inverted stacked light-emitting device 10B emits light when electrons injected from the first electrode 101 functioning as a cathode into the EL layer 103 and transported by the electron-transport layer 114 and holes injected from the second electrode 102 functioning as an anode into the EL layer 103 and transported by the hole-transport layer 112 are recombined in the light-emitting layer 113. Thus, in the light-emitting device 10B, the hole-transport layer 112 is positioned between the second electrode 102 and the light-emitting layer 113, and the electron-transport layer 114 is positioned between the first electrode 101 and the light-emitting layer 113.

In each of the light-emitting devices 10A and 10B, the electron-transport layer has a stacked-layer structure (a stack of the first electron-transport layer 114_1 and the second electron-transport layer 114_2). The hole-transport layer 112 may have a single-layer structure or a stacked-layer structure. Note that the first electron-transport layer 114_1 and the second electron-transport layer 114_2 are collectively referred to as the electron-transport layer 114 in some cases.

The light-emitting devices 10A and 10B each preferably include the hole-transport layer 112 between the anode and the light-emitting layer 113, and further preferably include a hole-injection layer 111 between the anode and the hole-transport layer 112. The light-emitting devices 10A and 10B each further preferably include an electron-injection layer 115 between the cathode and the electron-transport layer 114.

In the example illustrated in FIG. 1A, the ordered stacked light-emitting device 10A has a structure in which the hole-injection layer 111, the hole-transport layer 112, the light-emitting layer 113, the electron-transport layer 114, the electron-injection layer 115, and the second electrode 102 functioning as the cathode are stacked in this order over the first electrode 101 functioning as the anode. In the example illustrated in FIG. 1B, the inverted stacked light-emitting device 10B has a structure in which the electron-injection layer 115, the electron-transport layer 114, the light-emitting layer 113, the hole-transport layer 112, the hole-injection layer 111, and the second electrode 102 functioning as the anode are stacked in this order over the first electrode 101 functioning as the cathode.

Note that the structures of the light-emitting devices 10A and 10B are not limited to those illustrated in FIGS. 1A and 1B. For example, a structure may be employed which includes two hole-transport layers or which includes three or more hole-transport layers and/or three or more electron-transport layers.

The present inventors have found that the reliability of the light-emitting devices 10A and 10B in each of which the electron-transport layer has a stacked-layer structure can be improved by selecting materials used for the stacked layers in consideration of the slope of the giant surface potential (GSP) of the electron-transport layer.

That is, in the case where the electron-transport layer has a stacked-layer structure of the first electron-transport layer 114_1 formed earlier and the second electron-transport layer 114_2 formed later, each of the light-emitting devices can have high reliability when the slope of the GSP (GSP_Slope (mV/nm)) of the second electron-transport layer 114_2 is larger than the GSP_Slope of the first electron-transport layer 114_1.

Alternatively, in the case where the electron-transport layer has a stacked-layer structure of the first electron-transport layer 114_1 formed earlier and the second electron-transport layer 114_2 formed later, each of the light-emitting devices can have high reliability when the GSP_Slope (mV/nm) of a film of an organic compound having a T-electron deficient heteroaromatic ring in the second electron-transport layer 114_2 is larger than the GSP_Slope of a film of an organic compound having a π-electron deficient heteroaromatic ring in the first electron-transport layer 114_1.

Here, GSP is a phenomenon due to spontaneous orientation polarization (SOP) caused by deviation of permanent electric dipole moment orientation of an evaporated film to the thickness direction.

The surface potential of an evaporated film with GSP changes linearly with increasing thickness without saturation. For example, the surface potential of an evaporated film of tris(8-quinolinolato)aluminum (abbreviation: Alq₃) reaches approximately 28 V at a thickness of 560 nm. The electric field strength reaches 5×10⁵ V/cm, which is approximately the same level as electric field strength during driving of a general light-emitting device.

The slope of a GSP (GSP_Slope) is represented by ΔV/Δd, where ΔV (mV) is the amount of change in surface potential and Δd (nm) is the amount of change in the thickness of a film whose GSP changes in proportion to the thickness. Note that the GSP slope of a film whose surface potential increases with increasing thickness is positive, and the GSP slope of a film whose surface potential decreases with increasing thickness is negative. It can be said that Alq₃ mentioned above is a material with a positive GSP_Slope. The potential of a layer with a positive GSP_Slope is lower on the substrate side, and the potential of a layer with a negative GSP_Slope is higher on the substrate side.

As described above, GSP is a phenomenon due to SOP caused by deviation of permanent electric dipole moment orientation to the thickness direction. That is, the following phenomena can be regarded as occurring: a negative polarization charge is induced on the substrate side of a layer with a positive GSP_Slope, and a positive polarization charge is induced on the second electrode side of the layer; in a similar manner, a positive polarization charge is induced on the substrate side of a layer with a negative GSP_Slope, and a negative polarization charge is induced on the second electrode side of the layer. Thus, GSP originates in such phenomena. In FIGS. 1A and 1B, the degree of SOP caused by deviation of permanent electric dipole moment orientation to the thickness direction in each layer deposited by evaporation is indicated by σ+ or σ−; σ+ indicates positive polarization and σ− indicates negative polarization. A larger number of σ's in each layer in the vicinity of the interface with another layer means a higher degree of spontaneous polarization.

Evaporated films of organic compounds are likely to have a positive GSP_Slope. In this regard, when a second layer is formed over and in contact with a first layer, the first layer and the second layer both have positive GSP_Slopes, and it can be considered that a negative polarization charge is induced on the substrate side of each layer and a positive polarization charge is induced on the second electrode side of each layer. In that case, a negative polarization charge of the second layer on the first layer side is canceled out by a positive polarization charge of the first layer on the second layer side, and only a remaining charge can be regarded as an interface charge (fixed charge) at the interface between the first layer and the second layer. Note that a virtual charge that can be regarded as an interface charge is sometimes referred to as an interface charge in this specification and the like.

FIG. 1A illustrates the ordered stacked light-emitting device 10A, and FIG. 1B illustrates the inverted stacked light-emitting device 10B. The electron-transport layer 114 has the stacked-layer structure of the first electron-transport layer 114_1 and the second electron-transport layer 114_2. Note that the second electron-transport layer 114_2 is provided closer to the second electrode 102 than the first electron-transport layer 114_1 is. In each of the light-emitting devices of one embodiment of the present invention, the GSP_Slope of the second electron-transport layer 114_2 is preferably larger than the GSP_Slope of the first electron-transport layer 114_1. Alternatively, in each of the light-emitting devices of one embodiment of the present invention, the GSP_Slope of an evaporated film of a second organic compound having a π-electron deficient heteroaromatic ring in the second electron-transport layer 114_2 is preferably larger than the GSP_Slope of an evaporated film of a first organic compound having a π-electron deficient heteroaromatic ring in the first electron-transport layer 114_1.

In each of the light-emitting devices having such a structure of one embodiment of the present invention, a negative interface charge is generated at the interface between the second electron-transport layer 114_2 and the first electron-transport layer 114_1, which inhibits electron injection from the second electrode 102 or the electron-injection layer 115 into the second electron-transport layer 114_2 (in the case of the ordered stacked structure in FIG. 1A) or electron injection from the first electrode 101 or the electron-injection layer 115 into the first electron-transport layer 114_1 (in the case of the inverted stacked structure in FIG. 1B). This can prevent the light-emitting layer 113 from having excess electrons, inhibit deviation of a recombination region in the light-emitting layer 113 to the hole-transport layer 112 side, and inhibit degradation of the light-emitting layer 113 and the hole-transport layer 112 (or an electron-blocking layer). Accordingly, each of the light-emitting devices of one embodiment of the present invention can have high reliability.

Note that the light-emitting layer 113 contains at least a light-emitting substance and preferably further contains a host material. A blue-light-emitting substance having a high excitation energy level as a light-emitting substance needs a host material to have a large band gap and thus makes it difficult to control carrier balance. In particular, a blue phosphorescent light-emitting device containing a blue phosphorescent substance often has a structure in which the light-emitting layer 113 tends to have excess electrons. Thus, the present invention can be suitably applied to a phosphorescent light-emitting device, particularly a blue phosphorescent light-emitting device, and is significantly effective in improving the reliability.

In the ordered stacked light-emitting device 10A in FIG. 1A, the second electron-transport layer 114_2 may contain a first substance in addition to the second organic compound. The first substance is preferably a metal complex, particularly an organic complex including an alkali metal. Specific examples of the organic complex including an alkali metal include 8-quinolinolato-lithium (abbreviation: Liq), 8-quinolinolato-sodium (abbreviation: Naq), 8-quinolinolato-potassium (abbreviation: Kq), and derivatives thereof. When the second electron-transport layer 114_2 contains such a substance, the electron-transport property of the second electron-transport layer 114_2 can be controlled, and deviation of the recombination region in the light-emitting layer 113 to the hole-transport layer 112 side can be inhibited, whereby the reliability of the light-emitting device can be improved.

In the case where the mixing ratio (weight ratio) of the second organic compound to the first substance in the second electron-transport layer 114_2 is x:y, the GSP_Slope (mV/nm) of a film of the second organic compound is preferably larger than (x+y)/x times the GSP_Slope (mV/nm) of a film of the first organic compound. In that case, even when the GSP_Slope of the film of the first substance is smaller than the GSP_Slope of the film of the second organic compound, the GSP_Slope (mV/nm) of the second electron-transport layer 114_2 is larger than that of the first electron-transport layer 114_1, which is preferable because a negative interface charge can be generated and the electron-injection property can be lowered. Furthermore, y is preferably greater than x, in which case the proportion of the second organic compound responsible for electron transport can be lowered and the electron-transport property can be lowered.

In the inverted stacked light-emitting device 10B in FIG. 1B, the first electron-transport layer 114_1 may contain the first substance in addition to the first organic compound. The first substance is preferably a metal complex, particularly an organic complex including an alkali metal. When the first electron-transport layer 114_1 contains such a substance, the electron-transport property of the first electron-transport layer 114_1 can be controlled, and deviation of the recombination region in the light-emitting layer 113 to the hole-transport layer 112 side can be inhibited, whereby the reliability of the light-emitting device can be improved.

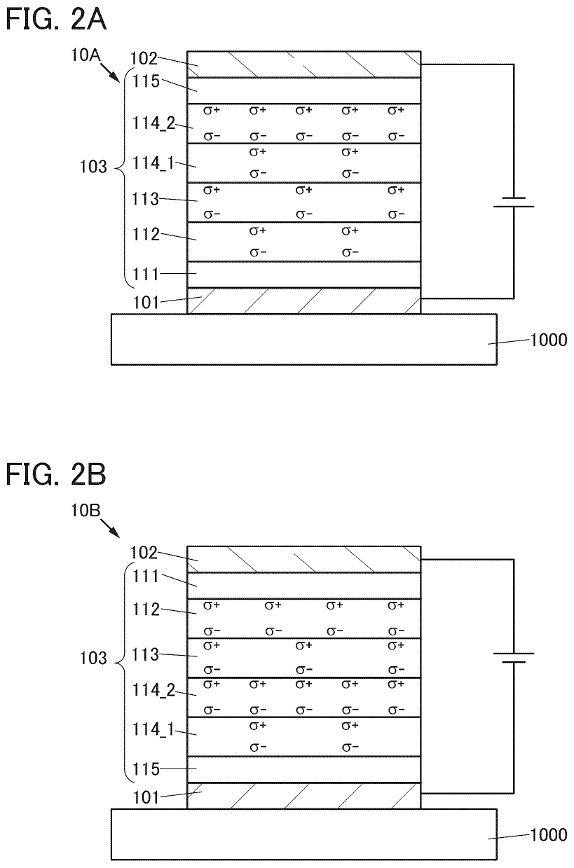

In the case where the ordered stacked light-emitting device of one embodiment of the present invention includes the hole-transport layer 112 in contact with the light-emitting layer 113, the GSP_Slope (mV/nm) of the light-emitting layer 113 is preferably larger than the GSP_Slope (mV/nm) of the hole-transport layer 112 or the GSP_Slope (mV/nm) of an evaporated film of a third organic compound having a π-electron rich heteroaromatic ring or an aromatic amine in the hole-transport layer 112, as illustrated in FIG. 2A. Alternatively, the GSP_Slope (m V/nm) of an evaporated film of the host material is preferably larger than the GSP_Slope (mV/nm) of the evaporated film of the third organic compound having a π-electron rich heteroaromatic ring or an aromatic amine in the hole-transport layer 112.

In the case where the inverted stacked light-emitting device of one embodiment of the present invention includes the hole-transport layer 112 in contact with the light-emitting layer 113, the GSP_Slope (m V/nm) of the light-emitting layer 113 is preferably smaller than the GSP_Slope (mV/nm) of the hole-transport layer 112 or the GSP_Slope (mV/nm) of the evaporation film of the third organic compound having a π-electron rich heteroaromatic ring or an aromatic amine in the hole-transport layer 112, as illustrated in FIG. 2B. Alternatively, the GSP_Slope (mV/nm) of the evaporated film of the host material is preferably smaller than the GSP_Slope (mV/nm) of the evaporated film of the third organic compound having a π-electron rich heteroaromatic ring or an aromatic amine in the hole-transport layer 112.

In each of the light-emitting devices having this structure of one embodiment of the present invention, hole injection from the hole-injection layer 111 into the hole-transport layer 112 is promoted by the effect of a negative interface charge derived from a difference in GSP_Slope between the two layers that are in contact with each other. Accordingly, holes can be effectively injected into the light-emitting layer, which improves the carrier balance and further expands the recombination region. Thus, degradation of the light-emitting layer 113 and the hole-transport layer 112 can be inhibited.

In the ordered stacked light-emitting device of one embodiment of the present invention, the GSP_Slope (mV/nm) of the light-emitting layer 113 is preferably larger than the GSP_Slope (mV/nm) of the first electron-transport layer 114_1, as illustrated in FIG. 1A. Alternatively, the GSP_Slope (mV/nm) of the evaporated film of the host material is preferably larger than the GSP_Slope (mV/nm) of the evaporated film of the first organic compound.

In the inverted stacked light-emitting device of one embodiment of the present invention, the GSP_Slope (mV/nm) of the light-emitting layer 113 is preferably smaller than the GSP_Slope (mV/nm) of the second electron-transport layer 114_2, as illustrated in FIG. 1B. Alternatively, the GSP_Slope (mV/nm) of the evaporated film of the host material is preferably smaller than the GSP_Slope (mV/nm) of the evaporated film of the second organic compound.

In each of the light-emitting devices having this structure of one embodiment of the present invention, electron injection from the second electron-transport layer 114_2 into the first electron-transport layer 114_1 is promoted by the effect of a positive interface charge derived from a difference in GSP_Slope between the two layers that are in contact with each other. Accordingly, each of the light-emitting devices of one embodiment of the present invention can have favorable characteristics without causing a significant increase in driving voltage even when electron injection from the first electrode 101 or the electron-injection layer 115 into the second electron-transport layer 114_2 is inhibited.

In the ordered stacked light-emitting device of one embodiment of the present invention, the GSP_Slope (mV/nm) of the second electron-transport layer 114_2 is preferably larger than the GSP_Slope (mV/nm) of the light-emitting layer 113, as illustrated in FIG. 1A. Alternatively, the GSP_Slope (mV/nm) of the evaporated film of the second organic compound is preferably larger than the GSP_Slope (mV/nm) of the evaporated film of the host material.

In the inverted stacked light-emitting device of one embodiment of the present invention, the GSP_Slope (m V/nm) of the first electron-transport layer 114_1 is preferably smaller than the GSP_Slope (mV/nm) of the light-emitting layer 113, as illustrated in FIG. 1B. Alternatively, the GSP_Slope (mV/nm) of the evaporated film of the first organic compound is preferably smaller than the GSP_Slope (mV/nm) of the evaporated film of the host material.

In each of the light-emitting devices having the structure of one embodiment of the present invention, the charge at the interface between the first electron-transport layer 114_1 and the second electron-transport layer 114_2 is negative and smaller than the charge at the interface between the light-emitting layer 113 and the first electron-transport layer 114_1. Owing to this effect, electron injection into the light-emitting layer is inhibited, whereas hole injection into the light-emitting layer is promoted. This improves the carrier balance and further expands the recombination region. Thus, degradation of the light-emitting layer 113 and the hole-transport layer 112 can be inhibited.

In the case where the light-emitting layer 113 contains a host material, the host material preferably contains a first material and a second material. The host material containing a plurality of materials facilitates carrier balance control and contributes to reliability improvement. Alternatively, an exciplex formed by the first material and the second material provides advantageous effects such as improving the efficiency of energy transfer to the light-emitting substance, decreasing the driving voltage, and improving the reliability. It is preferable that one of the first and second materials be an organic compound having a π-electron deficient heteroaromatic ring and the other be an organic compound having a π-electron rich heteroaromatic ring or an aromatic amine, in which case the carrier balance can be adjusted more easily.

In the case where the host material contains a plurality of materials, the GSP_Slope (mV/nm) of a mixed film formed by co-evaporation of the first material and the second material at 1:1 can be used as the GSP_Slope (mV/nm) of the film of the host material. Alternatively, the GSP_Slope (mV/nm) of an evaporated film of one of the first and second materials with a higher mixing ratio can be regarded as the GSP_Slope (mV/nm) of the film of the host material.

### <Method for Obtaining GSP_Slope>

Here, a method for obtaining the GSP_Slope of an organic compound film formed by a vacuum evaporation method will be described.

A phenomenon in which the surface potential of an evaporated film increases in proportion to the thickness of the film is called the giant surface potential as described above. In general, the slope of a plot of a surface potential of an evaporated film in the thickness direction by Kelvin probe measurement is assumed as the level of the giant surface potential, that is, a GSP_Slope (mV/nm); in the case where two different layers are stacked, a change in the density of charges (mC/m2) accumulated at the interface, which is in association with a GSP, can be utilized to estimate a GSP_Slope.

Non-Patent Document 1 discloses that the following formulae hold when voltage is applied to a stack of organic thin films (a thin film 1 positioned closer to the anode and a thin film 2 positioned closer to the cathode; the anode is positioned closer to the substrate) with different spontaneous polarizations and carriers accumulated at the interface are holes.

$$\begin{matrix}[ Formula 1 ] & \\ {σ}_{a c c} = ( {V}_{t h} - {V}_{inj} ) \frac{{ε}_{2}}{{d}_{2}} = - {σ}_{i n t} & ( 1 )\end{matrix}$$

$$\begin{matrix}[ Formula 2 ] & \\ {σ}_{i n t} = {P}_{1} - {P}_{2} = \frac{{ε}_{1} {V}_{1}}{{d}_{1}} - \frac{{ε}_{2} {V}_{2}}{{d}_{2}} & ( 2 )\end{matrix}$$

In Formula (1), σ_{acc} is the accumulated charge density, σᵢₙₜ is the interface charge density, Vᵢₙⱼ is the hole-injection voltage, Vₜₕ is the threshold voltage, d₂ is the thickness of the thin film 2, and ε₂ is the dielectric constant of the thin film 2. Note that Vᵢₙⱼ and Vₜₕ can be estimated from the capacitance-voltage characteristics of a device. The square of an ordinary refractive index nₒ (wavelength: 633 nm) can be used as the dielectric constant. As described above, according to Formula (1), the interface charge density σᵢₙₜ can be calculated using Vᵢₙⱼ and Vₜₕ estimated from the capacitance-voltage characteristics, the dielectric constant 22 of the thin film 2 calculated from the refractive index, and the thickness d₂ of the thin film 2.

Next, in Formula (2), Pₙ is the spontaneous polarization of the thin film n (n represents 1 or 2) in the direction normal to the substrate, εₙ is the dielectric constant of the thin film n, Vₙ is the potential of the surface of the film, and dₙ is the thickness of the thin film n. By dividing the potential of the film surface (Vₙ) by the thickness (dₙ), a GSP_Slope can be obtained. Since the interface charge density σᵢₙₜ can be obtained from Formula (1) above, the use of a substance with a known GSP_Slope for the thin film 2 and an appropriate dielectric constant enables the GSP_Slope of the thin film 1 to be estimated.

Hereinafter, an example is described in which the GSP_Slope of a film of 4,4′-bis[N-(1-naphthyl)-N-phenylamino]biphenyl (abbreviation: NPB) is obtained with use of a measurement device 1 fabricated using tris(8-quinolinolato)aluminum (abbreviation: Alq₃) whose GSP_Slope is known to be 48 (mV/nm) for the thin film 2.

Table 1 shows the device structure of the measurement device 1. Note that layers 1_1 to 4_1 and a cathode in the measurement device 1 are formed from an anode side by a vacuum evaporation method under the conditions where the substrate temperature is set to room temperature and the deposition rate ranges from 0.2 nm/s to 0.6 nm/s. Each layer is formed without interruption of evaporation. In the measurement device 1, the layer 2_1 corresponds to the thin film 1 and the layer 3_1 corresponds to the thin film 2. Note that OCHD-003 is an organic compound with an electron-accepting property.

In fabrication of the measurement device, the deposition rate of each layer is preferably within the range of 3 nm/min to 600 nm/min. The thickness of each layer in the measurement device is preferably greater than or equal to 3 nm and less than or equal to 500 nm, further preferably greater than or equal to 50 nm and less than or equal to 300 nm.

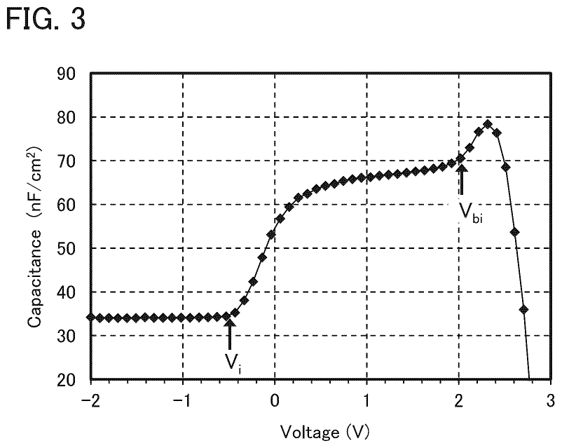

FIG. 3 shows the capacitance-voltage characteristics of the measurement device 1. Note that the capacitance-voltage characteristics are measured at room temperature at a frequency of 10 Hz with a potentiostat/galvanostat (SP-300 manufactured by BioLogic Science Instruments SAS (France)).

TABLE 1

| | Thickness | | Measurement device 1 |
|---|---|---|---|
| Cathode | 200 | nm | Al |
| Layer 4_1 | 1 | nm | LiF |
| Layer 3_1 | 60 | nm | Alq₃ |
| Layer 2_1 | 80 | nm | NPB |
| Layer 1_1 | 10 | nm | NPB:OCHD-003 (1:0.1) |
| Anode | 70 | nm | ITSO |

Table 2 shows the hole-injection voltage Vᵢₙⱼ, the threshold voltage Vₜₕ, the interface charge density σᵢₙₜ, SOP, and the GSP_Slope of the measurement device 1 that are obtained from FIG. 3 and Formulae (1) and (2) and the ordinary refractive index nₒ of a material used in the calculation. The refractive index is measured with a spectroscopic ellipsometer (M-2000U manufactured by J.A. Woollam Japan Corp.).

TABLE 2

Measurement device 1

| | | |
|---|---|---|
| Hole-injection voltage Vᵢₙⱼ | −0.53 | V |
| Threshold voltage Vₜₕ | 2.02 | V |
| Interface charge density σᵢₙₜ | −1.1 | mC/m² |
| Ordinary refractive index nₒ of Alq₃ | 1.71 | (@ 633 nm) |
| Ordinary refractive index nₒ of NPB | 1.77 | (@ 633 nm) |
| SOP of NPB | 0.14 | mC/m² |
| GSP_Slope of NPB | 5.2 | mV/nm |

Note that a measurement device 2 having substantially the same structure as the measurement device 1 except that the thickness of a film of Alq₃ is 80 nm is fabricated. It is confirmed that the hole-injection voltage of the measurement device 2 shifts to a lower voltage side than that of the measurement device 1. That is, it is presumed that holes are injected first and charges are accumulated at the interface with Alq₃ in such a device. Furthermore, the GSP_Slope is estimated for the measurement device 2 in a manner similar to that for the measurement device 1, and the same results as those of the measurement device 1 are obtained.

In the case where the threshold voltage Vₜₕ is difficult to estimate from the capacitance-voltage characteristics, a threshold voltage estimated from the current density-voltage characteristics may be used.

FIG. 4 shows the current density-voltage characteristics of the measurement device 1.

Note that Vₜₕ estimated from the current density-voltage characteristics is 2.0 V, which is equal to that estimated from the capacitance-voltage characteristics.

In this manner, a device in which a film of Alq₃ with a known GSP_Slope and a film of an organic compound whose GSP_Slope is to be obtained are stacked is fabricated and the capacitance-voltage characteristics are measured, so that the GSP_Slope of the organic compound can be estimated.

The above is the description of the method for calculating the GSP_Slope of the case where holes are carriers accumulated at the interface. In the case where electrons are carriers accumulated at the interface, the GSP_Slope of an organic film can be calculated in a similar manner using Formula (3) shown below.

$$\begin{matrix}[ Formula 3 ] & \\ {σ}_{a c c} = ( {V}_{t h} - {V}_{inj} ) \frac{{ε}_{1}}{{d}_{1}} = {σ}_{i n t} & ( 3 )\end{matrix}$$

Organic compounds used for layers of a light-emitting device are preferably selected in consideration of the GSP_Slopes of evaporated films of the organic compounds, which are measured in advance by the above measurement method.

The structures described in this embodiment can be used in combination with any of the structures described in the other embodiments, as appropriate.

### Embodiment 2

In this embodiment, light-emitting devices of one embodiment of the present invention will be described in detail.

FIGS. 1A to 2B are each a schematic view of a light-emitting device of one embodiment of the present invention. The light-emitting device includes the first electrode 101 over the substrate 1000 of an insulator, and the EL layer 103 between the first electrode 101 and the second electrode 102. The EL layer 103 in the light-emitting device includes the light-emitting layer 113, and the light-emitting layer 113 contains a light-emitting substance that emits light when voltage is applied between the first electrode 101 and the second electrode 102.

The EL layer 103 includes at least the first electron-transport layer 114_1 and the second electron-transport layer 114_2 in addition to the light-emitting layer 113 and has such a structure as described in Embodiment 1. The light-emitting device having the above structure of one embodiment of the present invention can have favorable characteristics, particularly high reliability.

Furthermore, the EL layer 103 preferably includes other functional layers such as the hole-injection layer 111, the hole-transport layer 112, and the electron-injection layer 115, as illustrated in FIGS. 1A to 2B. Note that the EL layer 103 may include functional layers other than the above functional layers, such as a hole-blocking layer, an electron-blocking layer, an exciton-blocking layer, and a charge-generation layer. Alternatively, any of the above layers may be omitted.

The first electrode 101 and the second electrode 102 each have a single-layer structure or a stacked-layer structure. In the case of the stacked-layer structure, a layer in contact with the EL layer 103 serves as an anode or a cathode. In the case where the electrodes each have the stacked-layer structure, there is no limitation on work functions of materials for layers other than the layer in contact with the EL layer 103, and the materials can be selected in accordance with required properties such as a resistance value, processing easiness, reflectivity, light-transmitting property, and stability.

The anode is preferably formed using a metal, an alloy, a conductive compound, or a mixture thereof each having a high work function (specifically, higher than or equal to 4.0 eV), for example. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), a nitride of a metal material (e.g., titanium nitride), or the like can be used for the anode. The anode may be a stack of layers formed using any of these materials. For example, a film in which Al, Ti, and ITSO are stacked in this order over Ti is preferable because the film has high efficiency owing to high reflectivity and enables a high resolution of several thousand ppi. Graphene can also be used for the anode. When a composite material that can be included in the hole-injection layer 111 described later is used for a layer (typically, the hole-injection layer) in contact with the anode, an electrode material can be selected regardless of its work function.

The hole-injection layer 111 is provided in contact with the anode and has a function of facilitating injection of holes into the EL layer 103. The hole-injection layer 111 can be formed using phthalocyanine (abbreviation: H2Pc), a phthalocyanine-based compound or a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-acceptor property. Examples of the substance having an acceptor property include organic compounds having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property that is used in the composite material preferably has a hole mobility higher than or equal to 1×10⁻⁶ cm²/Vs. The organic compound having a hole-transport property that is used in the composite material preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has at least one of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N′-bis(4-biphenyl)amino group to enable fabricating a light-emitting device having a long lifetime.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), NN-bis(4-biphenyl)benzo[b]naphtho[1,2-d]furan-6-amine (abbreviation: BBABnf(6)), NN-bis(4-biphenyl)benzo[b]naphtho[1,2-d]furan-8-amine (abbreviation: BBABnf(8)), NN-bis(4-biphenyl)benzo[b]naphtho[2,3-d]furan-4-amine (abbreviation: BBABnf(II)(4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-([2,1′-binaphthyl]-6-yl)triphenylamine (abbreviation: BBAαNβNB), 4,4′-diphenyl-4″-([2,1′-binaphthyl]-7-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-([2,2′-binaphthyl]-6-yl)triphenylamine (abbreviation: BBA(βN2)B), 4,4′-diphenyl-4″-([2,2′-binaphthyl]-7-yl)triphenylamine (abbreviation: BBA(βN2)B-03), 4,4′-diphenyl-4″-([1,2′-binaphthyl]-4-yl)triphenylamine (abbreviation: BBAβNαNB), 4,4′-diphenyl-4″-([1,2′-binaphthyl]-5-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiPNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N′-bis(biphenyl-4-yl)-9,9′-spirobi[9H-fluoren]-2-amine (abbreviation: BBASF), N,N′-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N′-bis(9,9-dimethyl-9H-fluoren-2-yl)-9,9′-spirobi-9H-fluoren-4-amine, N,N′-bis(9,9-dimethyl-9H-fluoren-2-yl)-9,9′-spirobi-9H-fluoren-3-amine, N,N′-bis(9,9-dimethyl-9H-fluoren-2-yl)-9,9′-spirobi-9H-fluoren-2-amine, and N,N′-bis(9,9-dimethyl-9H-fluoren-2-yl)-9,9′-spirobi-9H-fluoren-1-amine.

Examples of the aromatic amine compounds that can be used as the material with a hole-transport property include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because the organic compound is easily deposited by evaporation as a film.

The hole-transport layer 112 is formed using an organic compound having a hole-transport property. The organic compound having a hole-transport property preferably has a hole mobility of 1×10⁻⁶ cm²/Vs or higher.

Examples of the aforementioned material having a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), andN-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. Note that any of the substances given as examples of the material having a hole-transport property that is used for the composite material for the hole-injection layer 111 can also be suitably used as the material contained in the hole-transport layer 112. An organic compound having an amine skeleton and a fluorene skeleton is further preferably used. The organic compound having an amine skeleton and a fluorene skeleton is preferable because its high reliability and high hole-transport property enable power consumption of a light-emitting device to be reduced.

As the light-emitting substance, fluorescent substances, phosphorescent substances, substances exhibiting thermally activated delayed fluorescence (TADF), or other light-emitting substances may be used. Note that the present invention can be suitably applied to a light-emitting device using a blue-light-emitting substance, particularly a blue phosphorescent substance, as a light-emitting substance because the light-emitting layer 113 tends to have excess electrons.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A condensed heteroaromatic compound containing nitrogen and boron, especially a compound having a diaza-boranaphtho-anthracene skeleton, exhibits a narrow emission spectrum, emits blue light with high color purity, and can thus be used suitably. Examples of the compound include 5,9-diphenyl-5H,9H-[1,4]benzazaborino[2,3,4-kl]phenazaborine (abbreviation: DABNA-1), 9-(diphenyl-3-yl)-N,N,5,11-tetraphenyl-5,9-dihydro-5,9-diaza-13b-boranaphtho[3,2,1-de]anthracen-3-amine (abbreviation: DABNA-2), 2,12-di(tert-butyl)-5,9-di(4-tert-butylphenyl)-N,N′-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′: 4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, a compound having an indole skeleton, such as 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC)platinum(II) (abbreviation: PtON-TBBI). These compounds emit blue phosphorescent light and have an emission peak in the wavelength range from 450 nm to 520 nm. Alternatively, a compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-(methyl-d₃)-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and tris{2-[5-(methyl-d₃)-4-phenyl-2-pyridinyl-κN]phenyl-κC}iridium(III) (abbreviation: Ir(5m4dppy-d₃)₃); rare earth metal complexes such as tris(acetylacetonato)(monophenanthroline)terbium(III) (abbreviation: [Tb(acac)₃(Phen)]); and organometallic platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) and [2-(4-(3,5-di-tert-butylphenyl)-6-{3-[4-(5′-tert-butyl[1,1′:3′,1″-terphenyl]-2′-yl)-2-pyridinyl-κN]phenyl-κC²}-2-pyridinyl-κN)phenolato-κO]platinum(II) (abbreviation: Pt(4tButpppypyp-mmtBup)). These compounds mainly emit green phosphorescent light and have an emission peak in the wavelength range from 500 nm to 600 nm. Note that organometallic iridium complexes having a pyrimidine skeleton have distinctively high reliability or emission efficiency and thus are particularly preferable. A compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity. A compound obtained by substituting deuterium for part of hydrogen in any of these compounds can also be used.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

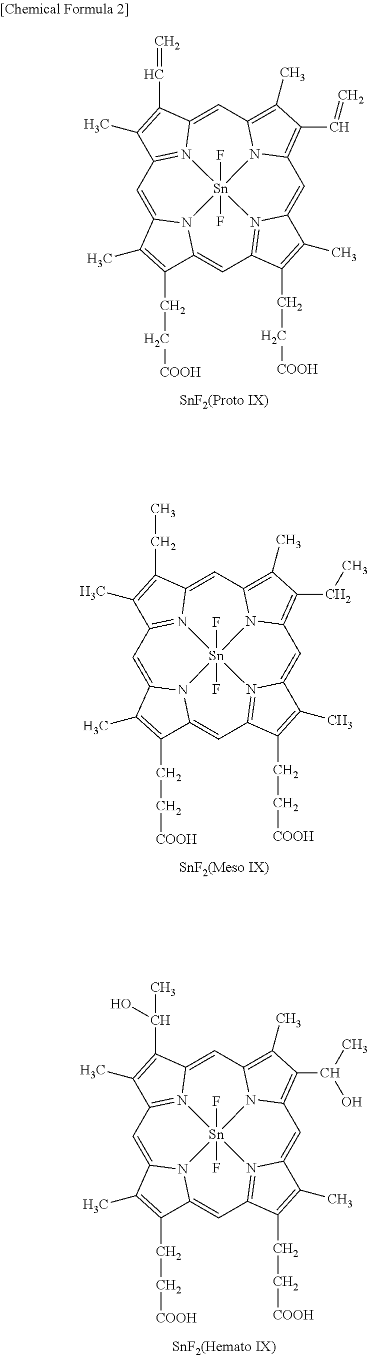

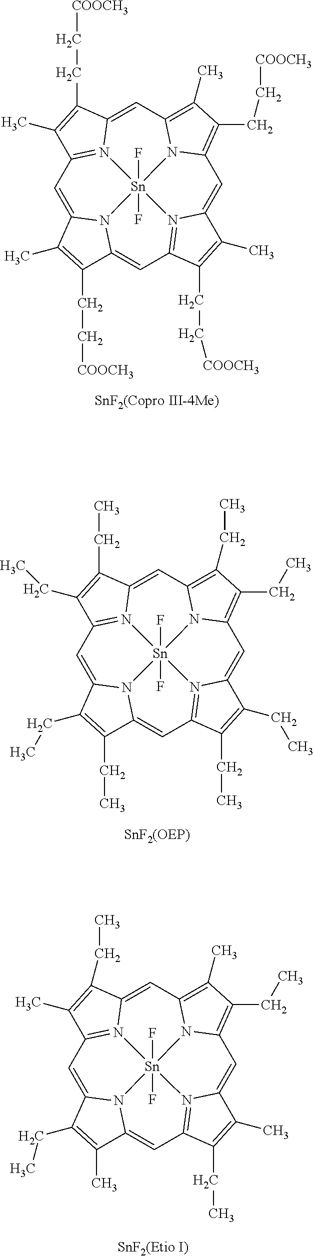

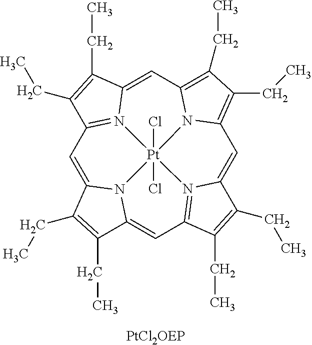

Alternatively, it is possible to use a heterocyclic compound having one or both of a π-electron rich heteroaromatic ring and a π-electron deficient heteroaromatic ring that is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

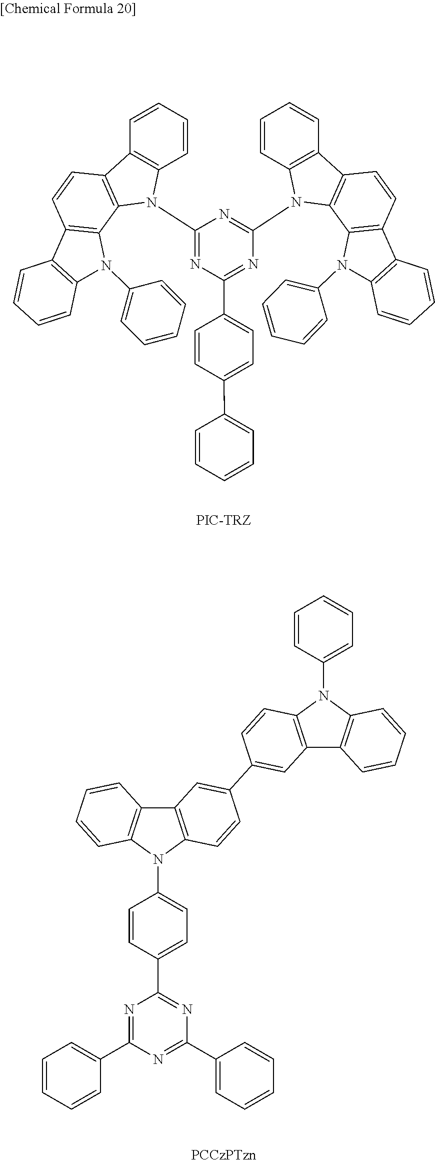 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

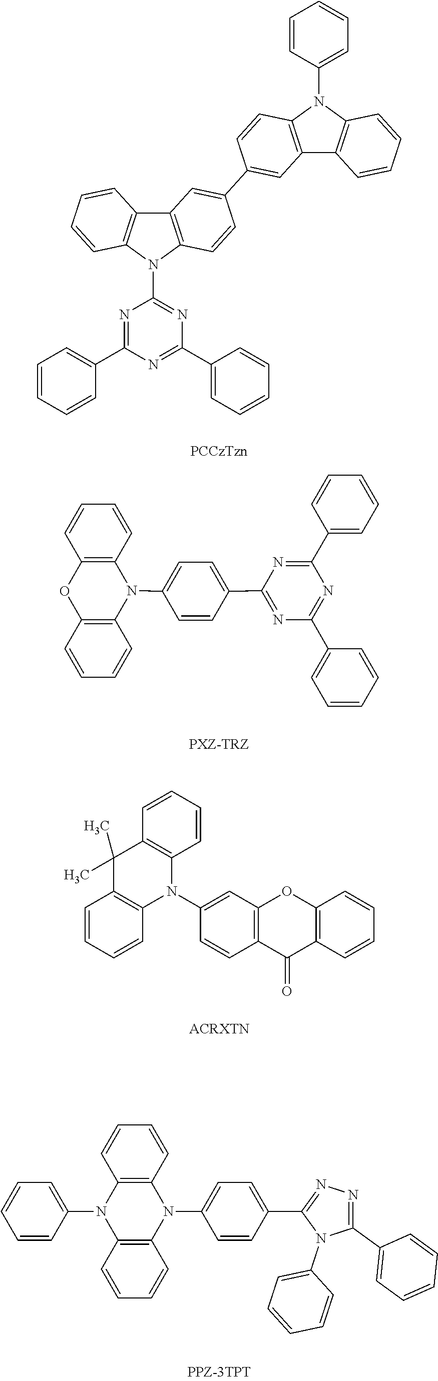 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1]

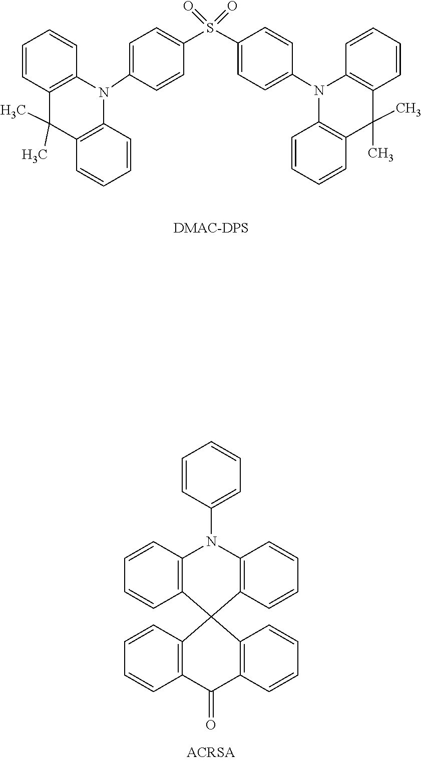

Note that a TADF material is a material having a small energy difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small energy difference between the S₁ level and the T₁ level and functions as a TADF material capable of converting triplet excitation energy into singlet excitation energy.

A phosphorescence spectrum observed at a low temperature (e.g., 77 K to 10 K) is used for an index of the T₁ level. When the level of energy with a wavelength of a line obtained by extrapolating a tangent to the fluorescence spectrum at a tail on the shorter wavelength side is the S₁ level and the level of energy with a wavelength of a line obtained by extrapolating a tangent to the phosphorescence spectrum at a tail on the shorter wavelength side is the T₁ level, the energy difference between the S₁ level and the T₁ level of the TADF material is preferably less than or equal to 0.3 eV, further preferably less than or equal to 0.2 eV.

When the TADF material is used as a light-emitting substance, the S₁ level of the host material is preferably higher than that of the TADF material, and the T₁ level of the host material is preferably higher than that of the TADF material.

As the host material in the light-emitting layer, any of various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has at least one of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Examples of such an organic compound include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: Bis3NCz),9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used. An organic compound having an amine skeleton and a fluorene skeleton is further preferably used. The organic compound having an amine skeleton and a fluorene skeleton is preferable because its high reliability and high hole-transport property enable power consumption of a light-emitting device to be reduced.

The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property.

As the material having an electron-transport property, for example, a metal complex such as tris(8-quinolinolato)aluminum (abbreviation: Alq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq),bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferably used. Examples of the organic compound having a π-electron deficient heteroaromatic ring skeleton include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above materials, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOs), or 2-{4-[9,10-di(2-naphthyl)-2-anthryl]phenyl}-1-phenyl-1H-benzimidazole (abbreviation: ZADN); an organic compound that has a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-{3-[3-(N-phenyl-9H-carbazol-3-yl)-9H-carbazol-9-yl]phenyl}dibenzo[f,h]quinoxaline (abbreviation: 2mPCCzPDBq), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 11-[3′-(dibenzothiophen-4-yl)biphenyl-3-yl]phenanthro[9′,10′:4,5]furo[2,3-b]pyrazine (abbreviation: 11mDBtBPPnfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-([2,2′-binaphthalen]-6-yl)-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 8-(biphenyl-4-yl)-4-[3′-(dibenzothiophen-4-yl)biphenyl-3-yl]-[1]benzofuro[3,2-d]pyrimidine (abbreviation: 8BP-4mDBtBPBfpm), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), or 7-[4-(9-phenyl-9H-carbazol-2-yl)quinazolin-2-yl]-7H-dibenzo[c,g]carbazole (abbreviation: PC-cgDBCzQz); and an organic compound that has a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-[8-([1,1′:4′,1″-terphenyl]-4-yl)-1-dibenzofuranyl]-1,3,5-triazine (abbreviation: mBP-TPDBfTzn), 2-(3″,5′,5″-tri-t-butyl-[1,1′:3′,1″-terphenyl]-4-yl-4,6-diphenyl-1,3,5-triazine (abbreviation: mmtBumTPTzn-04), 2,4,6-tris[3′-(pyridin-3-yl)-5′-tert-butyl-biphenyl-3-yl]-1,3,5-triazine (abbreviation: tBu-TmPPPyTz), 2,4,6-tris[3′-(pyridin-3-yl)-5′-tert-butyl-biphenyl-4-yl]-1,3,5-triazine (abbreviation: tBu-TmPPPyTz-02), 2-(3″,5′,5″-tri-t-butyl-[1,1′:3′,1″-terphenyl]-5-yl)-4,6-diphenyl-1,3,5-triazine (abbreviation: mmtBumTPTzn-03), or 2-{3-(2,6-dimethylpyridin-3-yl)-5-[(3,5-di-tert-butyl)phenyl]phenyl}-4,6-diphenyl-1,3,5-triazine (abbreviation: mmtBuPh-mDMePyPTzn). The organic compound that has a heteroaromatic ring having a diazine skeleton, the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. Among the above organic compounds, 8BP-4mDBtBPBfpm, 4,6mDBTP2Pm-II, 8mpTP-4mDBtPBfpm, TPBI, ZADN, BP-ICz(II)Tzn, mmtBumTPTzn-04, tBu-TmPPPyTz, tBu-TmPPPyTz-02, mmtBumTPTzn-03, mmtBuPh-mDMePyPTzn, and 4,8mDBtP2Bfpm as well as Alq₃ each have a large GSP_Slope in an evaporated film state and thus can be suitably used as a material for the second electron-transport layer in the light-emitting device of the present invention.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of the lowest-energy-side absorption band of the fluorescent substance. This enables smooth transfer of excitation energy from the TADF material to the fluorescent substance and accordingly enables efficient light emission, which is preferable.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably has an aromatic ring, and still further preferably has a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an acene skeleton, especially an anthracene skeleton, is suitably used as the host material. The use of a substance having an anthracene skeleton as the host material for the fluorescent substance makes it possible to obtain a light-emitting layer with high emission efficiency and high durability. Among the substances having an anthracene skeleton that are used as the host materials, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further condensed to a carbazole skeleton, because the highest occupied molecular orbital (HOMO) level of the host material having a benzocarbazole skeleton is higher than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is higher than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used.

Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthryl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength of the lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the lowest unoccupied molecular orbital (LUMO) level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a material having an electron-transport property. The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property. The above organic compound is preferably an organic compound that has a π-electron deficient heteroaromatic ring. The organic compound that has a π-electron deficient heteroaromatic ring is preferably one or more of an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

As the organic compound having an electron-transport property that can be used in the electron-transport layer 114, any of the organic compounds that can be used as the organic compound having an electron-transport property in the light-emitting layer 113 can be similarly used. Among the above organic compounds, the organic compound that has a heteroaromatic ring having a diazine skeleton, the organic compound that has a heteroaromatic ring having a pyridine skeleton, and the organic compound that has a heteroaromatic ring having a triazine skeleton are especially preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of high stability.

Note that the electron-transport layer 114 may have a stacked-layer structure. A layer in the stacked-layer structure of the electron-transport layer 114, which is in contact with the light-emitting layer 113, may function as a hole-blocking layer. In the case where the electron-transport layer in contact with the light-emitting layer functions as a hole-blocking layer, the electron-transport layer is preferably formed using a material having a lower HOMO level than a material contained in the light-emitting layer 113 by greater than or equal to 0.5 eV.

A layer that contains a compound or a complex of an alkali metal or an alkaline earth metal, such as 8-quinolinolato-lithium (abbreviation: Liq), 1,1′-pyridine-2,6-diyl-bis(1,3,4,6,7,8-hexahydro-2H-pyrimido[1,2-a]pyrimidine) (abbreviation: hpp2Py), or the like may be provided as the electron-injection layer 115. As the electron-injection layer 115, an alkali metal, an alkaline earth metal, or a compound thereof may be contained in a layer formed using a substance having an electron-transport property.

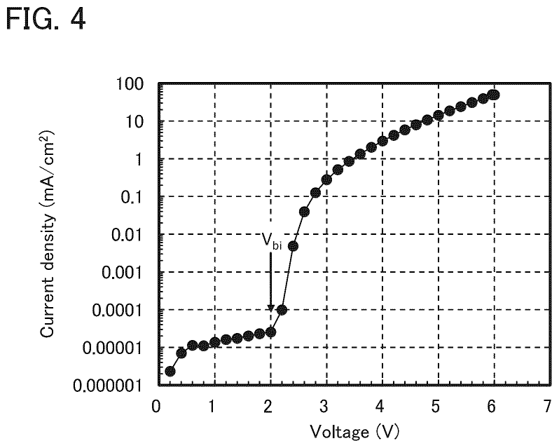

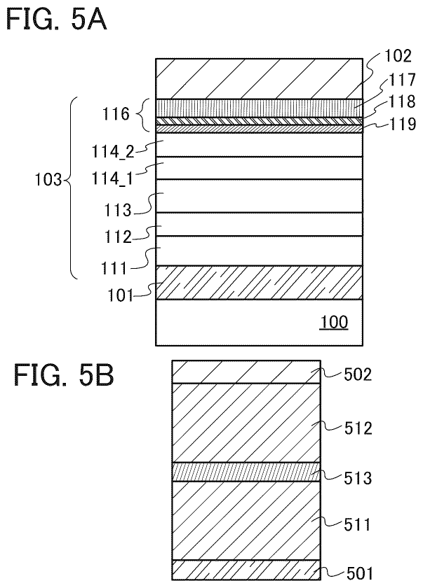

Instead of the electron-injection layer 115, a charge-generation layer 116 may be provided (FIG. 5A). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates. Since the organic compound of one embodiment of the present invention has a low refractive index in a film state, using the organic compound for the p-type layer 117 enables the light-emitting device to have high external quantum efficiency.

Note that the charge-generation layer 116 preferably includes one or both of an electron-relay layer 118 and an electron-injection buffer layer 119 in addition to the p-type layer 117.

The electron-relay layer 118 contains at least a substance having an electron-transport property and has a function of preventing an interaction between the electron-injection buffer layer 119 and the p-type layer 117 and smoothly transferring electrons. The LUMO level of the substance having an electron-transport property that is contained in the electron-relay layer 118 is preferably between the LUMO level of the acceptor substance in the p-type layer 117 and the LUMO level of a substance contained in a layer of the electron-transport layer 114 that is in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

The electron-injection buffer layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

The second electrode 102 includes the cathode. The second electrode 102 may have a stacked-layer structure, in which case a layer in contact with the EL layer 103 functions as the cathode. The cathode is preferably formed using a metal, an alloy, an electrically conductive compound, or a mixture thereof each having a low work function (specifically, lower than or equal to 3.8 eV), for example. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The EL layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure in which a plurality of light-emitting units are stacked (this type of light-emitting device is also referred to as a stacked or tandem element) is described with reference to FIG. 5B. This light-emitting device includes a plurality of light-emitting units between an anode and a cathode. One light-emitting unit has substantially the same structure as the EL layer 103 illustrated in FIGS. 1A to 2B. In other words, the light-emitting device illustrated in FIG. 5B includes a plurality of light-emitting units, and the light-emitting device illustrated in FIGS. 1A to 2B includes a single light-emitting unit.

In FIG. 5B, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIGS. 1A to 2B, and can be formed using the materials given in the description for FIGS. 1A to 2B. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 5B, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 5A. A composite material of an organic compound and a metal oxide enables low-voltage driving and low-current driving because of having an excellent carrier-injection property and an excellent carrier-transport property.

In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 functions as an electron-injection layer in the light-emitting unit on the anode side; thus, an electron-injection layer is not necessarily formed in the light-emitting unit on the anode side.

The light-emitting device having two light-emitting units is described with reference to FIG. 5B; however, one embodiment of the present invention can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The EL layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an inkjet method), a coating method, or a gravure printing method. A low molecular material, a middle molecular material (including an oligomer and a dendrimer), or a high molecular material may be included in the above components.

### Embodiment 3

Described in this embodiment is an example in which the light-emitting device of one embodiment of the present invention is used as a display element of a display device. Note that although a light-emitting device shown in this embodiment is formed by a photolithography method, the light-emitting device may be formed by a method using a fine metal mask or the like.

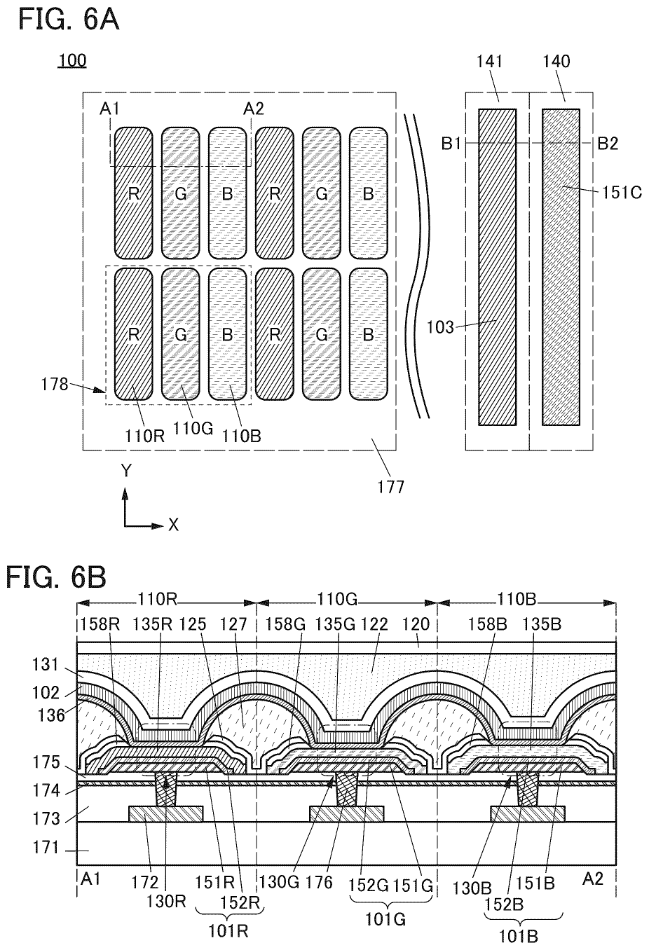

As illustrated in FIGS. 6A and 6B, a plurality of light-emitting devices 130 are formed over an insulating layer 175 to constitute a display device.

A display device 100 includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals without the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 6A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The EL layer 103 is provided in the region 141. A conductive layer 151C is provided in the connection portion 140.

Although FIG. 6A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 6B is an example of a cross-sectional view along the dashed-dotted line A1-A2 in FIG. 6A. As illustrated in FIG. 6B, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 6B illustrates cross sections of a plurality of inorganic insulating layers 125 and a plurality of insulating layers 127, the inorganic insulating layers 125 are preferably connected to each other and the insulating layers 127 are preferably connected to each other when the display device is seen from above. That is, the inorganic insulating layer 125 and the insulating layer 127 preferably include opening portions over first electrodes.

In FIG. 6B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light. It can be said that in FIG. 6B, the light-emitting devices 130R and 130G are adjacent light-emitting devices and the light-emitting devices 130G and 130B are adjacent light-emitting devices.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R emits red light (preferably phosphorescent light), and preferably has the structure shown in Embodiment 2. The light-emitting device 130R includes a first electrode (pixel electrode) 101R including a conductive layer 151R and a conductive layer 152R, a first layer 135R over the first electrode 101R, a common layer 136 over the first layer 135R, and the second electrode (common electrode) 102 over the common layer 136. The common layer 136 is preferably an electron-injection layer.

The light-emitting device 130G emits green light (preferably phosphorescent light), and preferably has the structure shown in Embodiment 2. The light-emitting device 130G includes a first electrode (pixel electrode) 101G including a conductive layer 151G and a conductive layer 152G, a first layer 135G over the first electrode 101G, the common layer 136 over the first layer 135G, and the second electrode (common electrode) 102 over the common layer 136. The common layer 136 is preferably an electron-injection layer.

The light-emitting device 130B emits blue light (preferably fluorescent light), and preferably has the structure shown in Embodiment 2. The light-emitting device 130B includes a first electrode (pixel electrode) 101B including a conductive layer 151B and a conductive layer 152B, a first layer 135B over the first electrode 101B, the common layer 136 over the first layer 135B, and the second electrode (common electrode) 102 over the common layer 136. The common layer 136 is preferably an electron-injection layer.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified.

The first layers 135R, 135G, and 135B are island-shaped layers that are independent of each other on a light-emitting device basis or on an emission color basis. It is preferable that the first layers 135R, 135G, and 135B not overlap with one another. The first layers included in the plurality of light-emitting devices 130 formed in the light-emitting apparatus, such as the first layers 135R, 135G, and 135B, are collectively referred to as a first layer group 135A in some cases. Providing the island-shaped first layer group 135A in the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped first layer group 135A is formed by forming an EL film for each emission color and processing the EL film by a photolithography method.

The first layer 135 is preferably provided to cover the top surface and the side surface of the first electrode 101 (pixel electrode) of the light-emitting device 130. In this case, the aperture ratio of the display device can be easily increased as compared to the structure where an end portion of the first layer 135 is positioned inward from an end portion of the pixel electrode. Covering the side surface of the pixel electrode of the light-emitting device 130 with the first layer 135 can inhibit the first electrode 101 from being in contact with the second electrode 102; hence, a short circuit of the light-emitting device 130 can be inhibited.

In the display device of one embodiment of the present invention, the first electrode 101 (pixel electrode) of the light-emitting device preferably has a stacked-layer structure. For example, in the example illustrated in FIG. 6B, the first electrode 101 of the light-emitting device 130 has a stacked-layer structure of the conductive layer 151 provided on the insulating layer 171 side and the conductive layer 152 provided on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a work function higher than or equal to 4.0 eV, for example.

The conductive layer 151 and the conductive layer 152 may each be a stack of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that the conductive layer 151 preferably has a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the first layer 135 provided along the side surface of the conductive layer 152 can be improved.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a virtual reality (VR) device like a head mounted display (HMD) and a glasses-type augmented reality (AR) device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

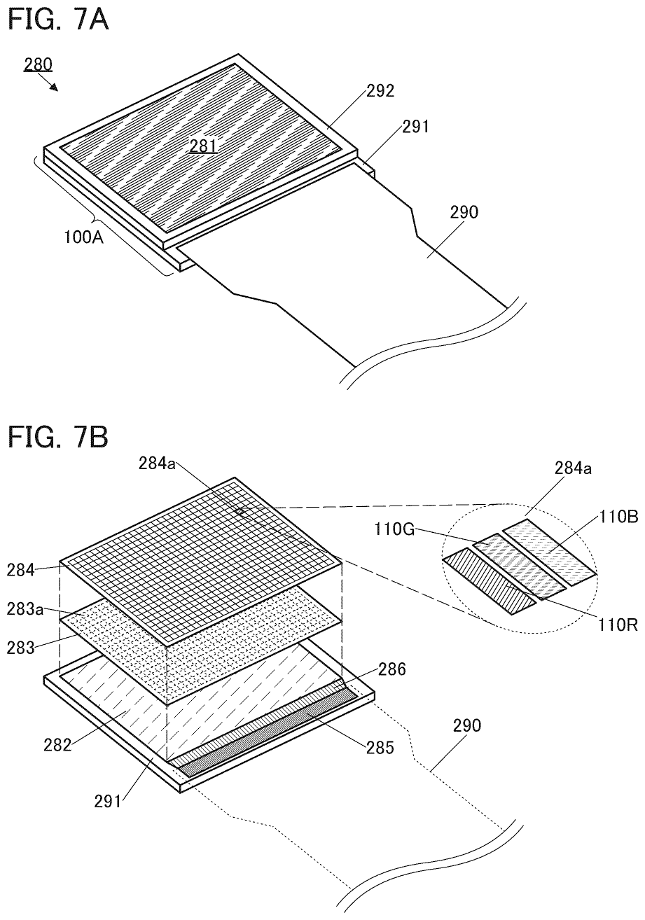

FIG. 7A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 7B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 7B. The pixels 284a can employ any of the structures described in the above embodiments. FIG. 7B illustrates an example where the pixel 284a has a structure similar to that of the pixel 178 illustrated in FIG. 6A.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both ofa gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An integrated circuit (IC) may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

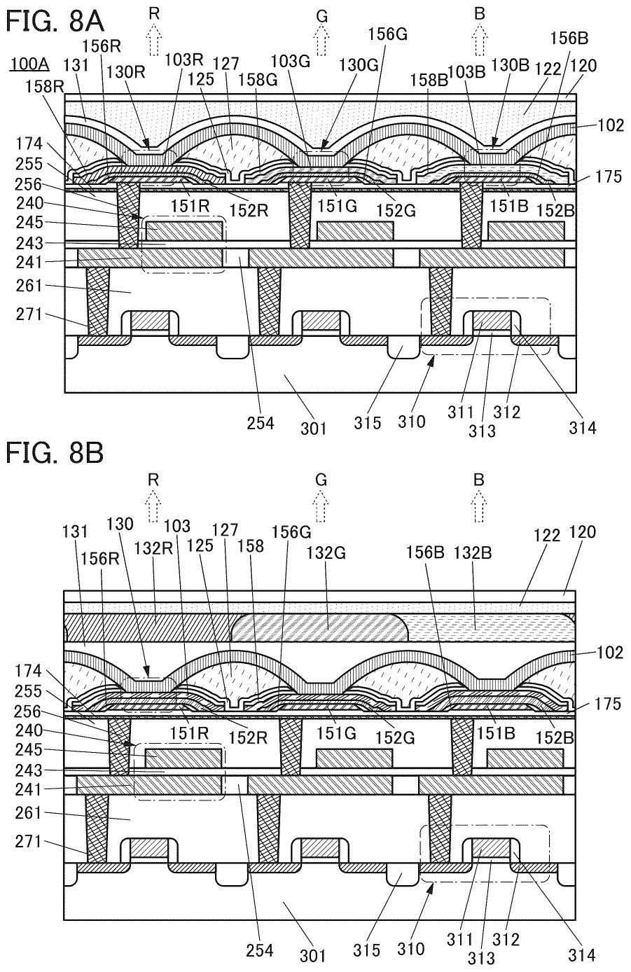

The display device 100A illustrated in FIG. 8A includes a substrate 301, the light-emitting devices 130R, 130G, and 130B, a capacitor 240, and a transistor 310.

The substrate 301 corresponds to the substrate 291 in FIGS. 7A and 7B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

An insulating layer 156R is provided to include a region overlapping with the side surface of the conductive layer 151R. An insulating layer 156G is provided to include a region overlapping with the side surface of the conductive layer 151G. An insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the first layer 135R. A sacrificial layer 158G is positioned over the first layer 135G. A sacrificial layer 158B is positioned over the first layer 135B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 7A.

FIG. 8B illustrates a variation example of the display device 100A illustrated in FIG. 8A. The display device illustrated in FIG. 8B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 8B, the light-emitting device 130 can emit white light, for example. The coloring layer 132R, the coloring layer 132G, and the coloring layer 132B can transmit red light, green light, and blue light, respectively, for example.

### [Display Device 100B]

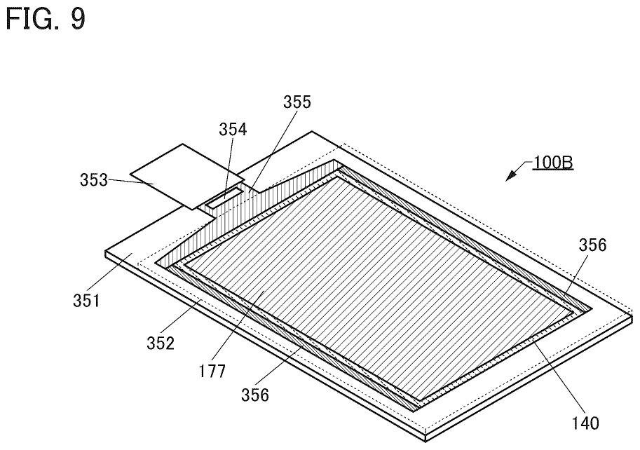

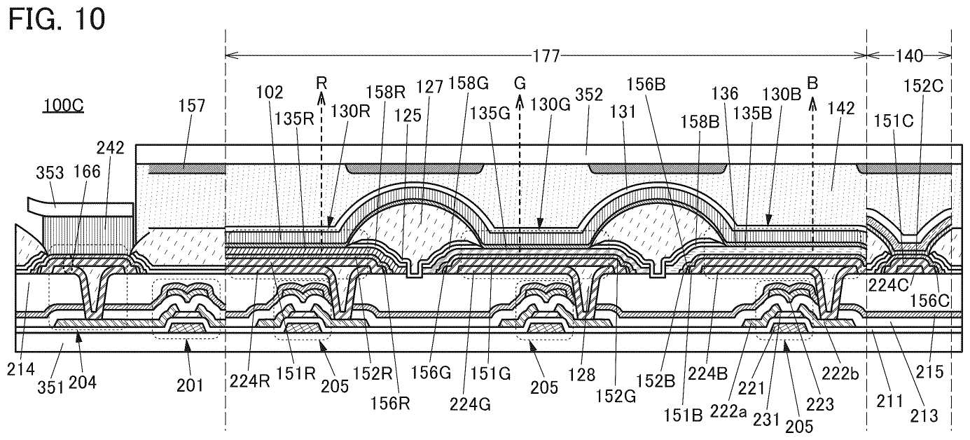

FIG. 9 is a perspective view of the display device 100B, and FIG. 10 is a cross-sectional view of the display device 100C.

In the display device 100B, a substrate 352 and a substrate 351 are bonded to each other. In FIG. 9, the substrate 352 is denoted by a dashed line.

The display device 100B includes the pixel portion 177, the connection portion 140, a circuit 356, a wiring 355, and the like. FIG. 9 illustrates an example where an IC 354 and an FPC 353 are mounted on the display device 100B. Thus, the structure illustrated in FIG. 9 can be regarded as a display module including the display device 100B, the IC, and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 9 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 10 illustrates an example of cross sections of part of a region including the FPC 353, part of the circuit 356, part of the pixel portion 177, part of the connection portion 140, and part of a region including an end portion of the display device 100C.

### [Display Device 100C]

The display device 100C illustrated in FIG. 10 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 10, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided in a frame shape not to overlap with the light-emitting device. Furthermore, the space may be filled with a resin other than the frame-shaped adhesive layer 142.

FIG. 10 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and a conductive layer 152C obtained by processing the same conductive film as the conductive layers 152R, 152G, and 152B. In the example illustrated in FIG. 10, an insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. In the case where the light-emitting device emits infrared or near-infrared light, a material having a high transmitting property with respect to infrared or near-infrared light is preferably used. The first electrode (pixel electrode) contains a material that reflects visible light, and the second electrode (counter electrode) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the wiring 355 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

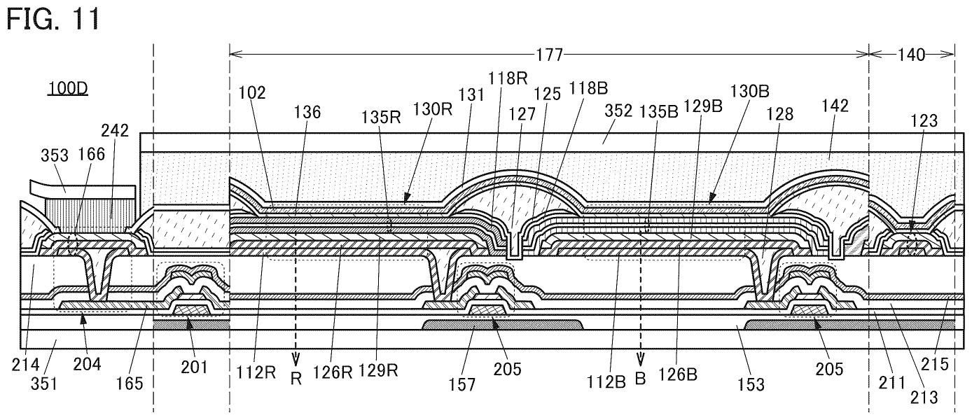

The display device 100D illustrated in FIG. 11 differs from the display device 100C illustrated in FIG. 10 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

The light-blocking layer 157 is preferably formed between the substrate 351 and the transistor 201 and between the substrate 351 and the transistor 205. FIG. 11 illustrates an example where the light-blocking layer 157 is provided over the substrate 351, an insulating layer 153 is provided over the light-blocking layer 157, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode.

Although not illustrated in FIG. 11, the light-emitting device 130G is also provided.

Although FIG. 11 and the like illustrate an example where the top surface of the layer 128 includes a flat portion, the shape of the layer 128 is not particularly limited.

### [Display Device 100E]

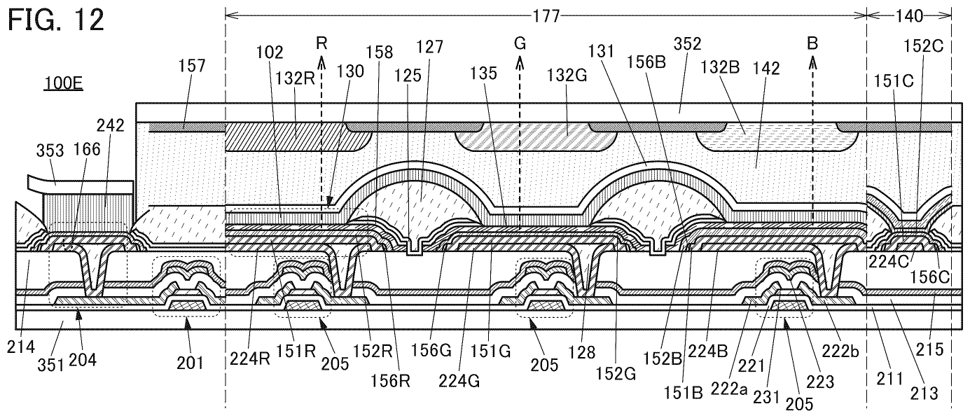

The display device 100E illustrated in FIG. 12 is a variation example of the display device 100C illustrated in FIG. 10 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

Although FIG. 10, FIG. 12, and the like illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances in this embodiment each include the display device of one embodiment of the present invention in a display portion. The display device of one embodiment of the present invention has low power consumption. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention has low power consumption, and thus can be suitably used for a relatively small electronic appliance. Examples of such an electronic appliance include watch-type and bracelet-type information terminals (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

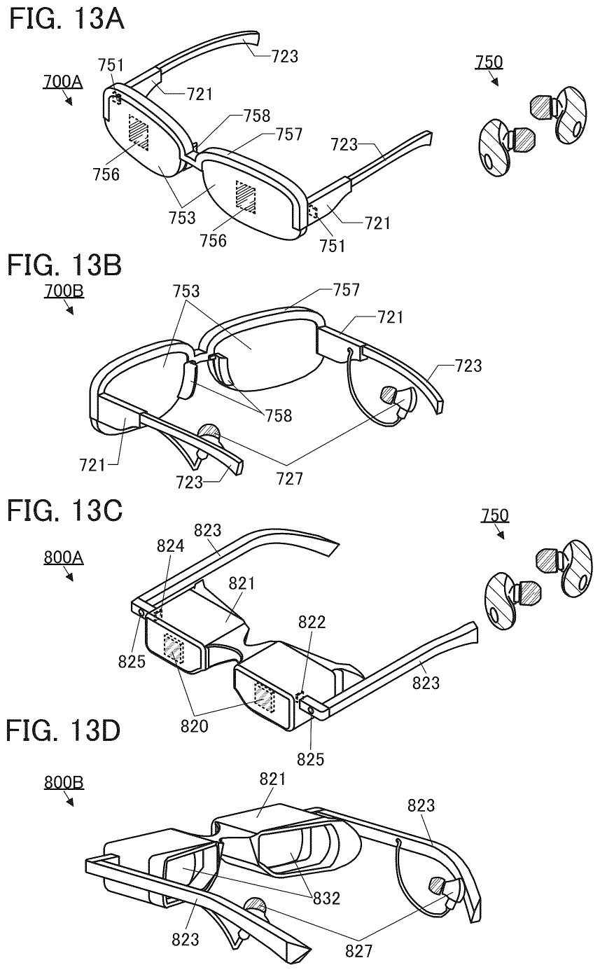

Examples of wearable devices capable of being worn on a head are described with reference to FIGS. 13A to 13D.

An electronic appliance 700A illustrated in FIG. 13A and an electronic appliance 700B illustrated in FIG. 13B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic appliance can have low power consumption and be driven for a long time.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 13C and an electronic appliance 800B illustrated in FIG. 13D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic appliance can have low power consumption and be driven for a long time.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 13B includes earphone portions 727. Part of a wiring that connects the earphone portion 727 and the control portion may be positioned inside the housing 721 or the wearing portion 723.

Similarly, the electronic appliance 800B illustrated in FIG. 13D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

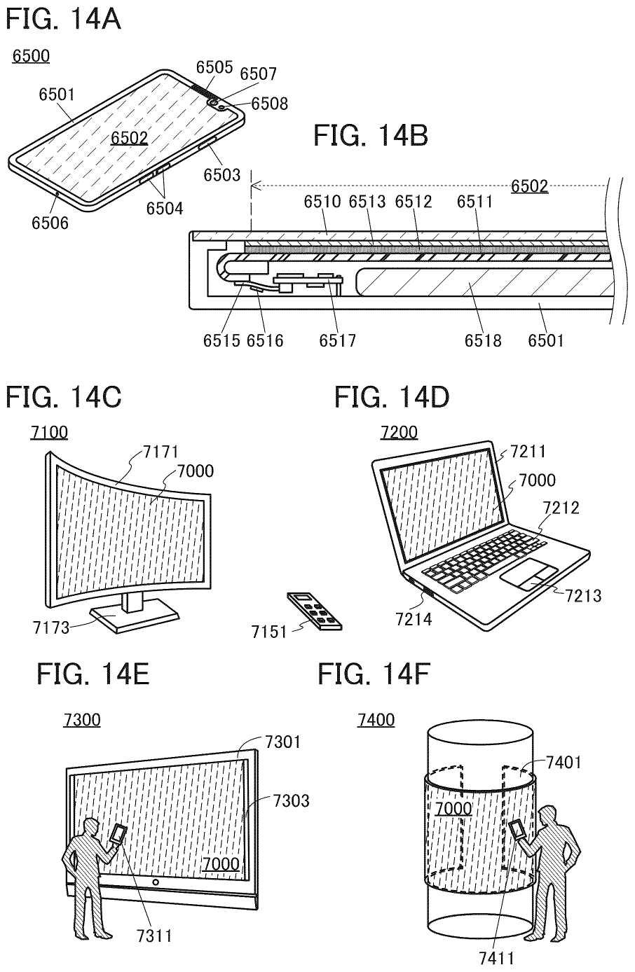

An electronic appliance 6500 illustrated in FIG. 14A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic appliance can have low power consumption and be driven for a long time.

FIG. 14B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 14C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, the electronic appliance can have low power consumption and be driven for a long time.

Operation of the television device 7100 illustrated in FIG. 14C can be performed with an operation switch provided in the housing 7171 and a separate remote control 7151.

FIG. 14D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, the electronic appliance can have low power consumption and be driven for a long time.

FIGS. 14E and 14F illustrate examples of digital signage.

Digital signage 7300 illustrated in FIG. 14E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 14F illustrates digital signage 7400 attached to a cylindrical pillar 7401. The digital signage 7400 includes the display portion 7000 provided along a curved surface of the pillar 7401.

In FIGS. 14E and 14F, the display device of one embodiment of the present invention can be used in the display portion 7000. Thus, a highly reliable electronic appliance can be obtained.

A larger area of the display portion 7000 can increase the amount of information that can be provided at a time. The larger display portion 7000 attracts more attention, so that the effectiveness of the advertisement can be increased, for example.

As illustrated in FIGS. 14E and 14F, it is preferable that the digital signage 7300 or the digital signage 7400 can work with an information terminal 7311 or an information terminal 7411, such as a smartphone that a user has, through wireless communication.

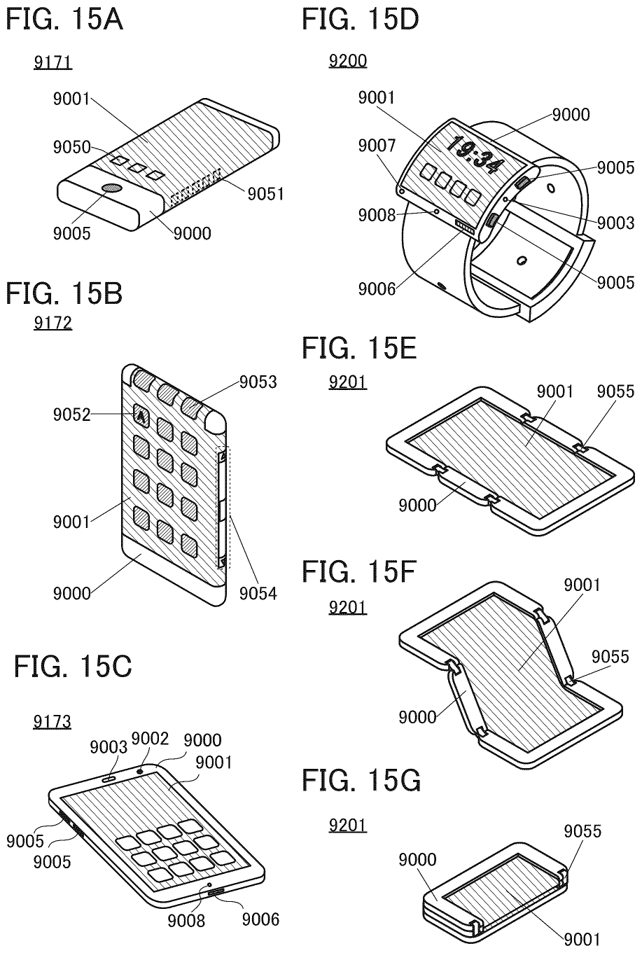

Electronic appliances illustrated in FIGS. 15A to 15G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 15A to 15G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 15A to 15G are described in detail below.

FIG. 15A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 15A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 15B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 15C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 15D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 15E to 15G are perspective views of a foldable portable information terminal 9201. FIG. 15E is a perspective view illustrating the portable information terminal 9201 that is opened. FIG. 15G is a perspective view illustrating the portable information terminal 9201 that is folded. FIG. 15F is a perspective view illustrating the portable information terminal 9201 that is shifted from one of the states in FIGS. 15E and 15G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Described in this example are specific methods for fabricating a light-emitting device 1-1, a light-emitting device 1-2, and a light-emitting device 1-3 and characteristics of the light-emitting devices. Structural formulae of main compounds used in this example are shown below.

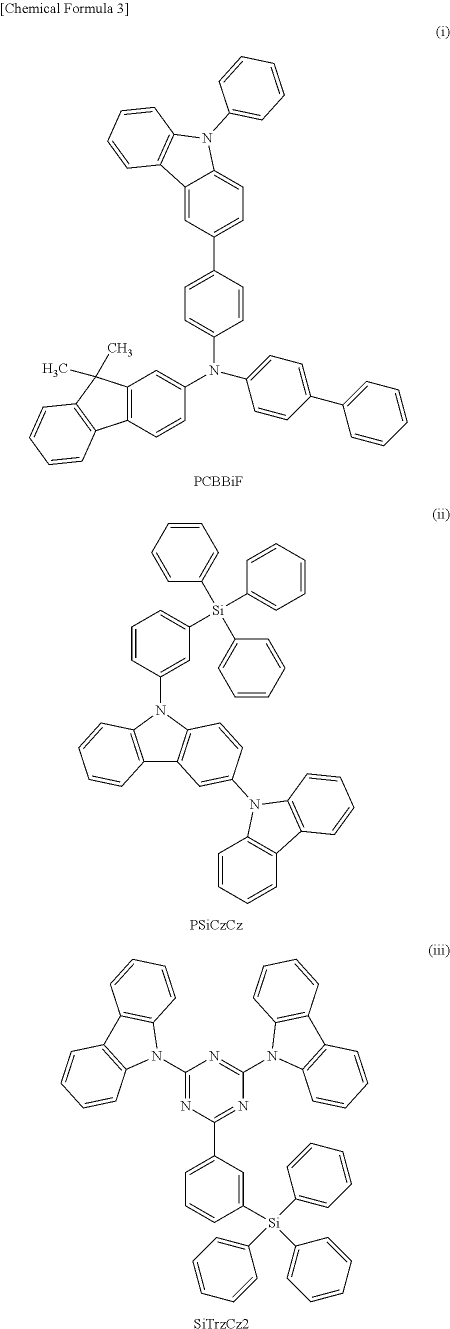

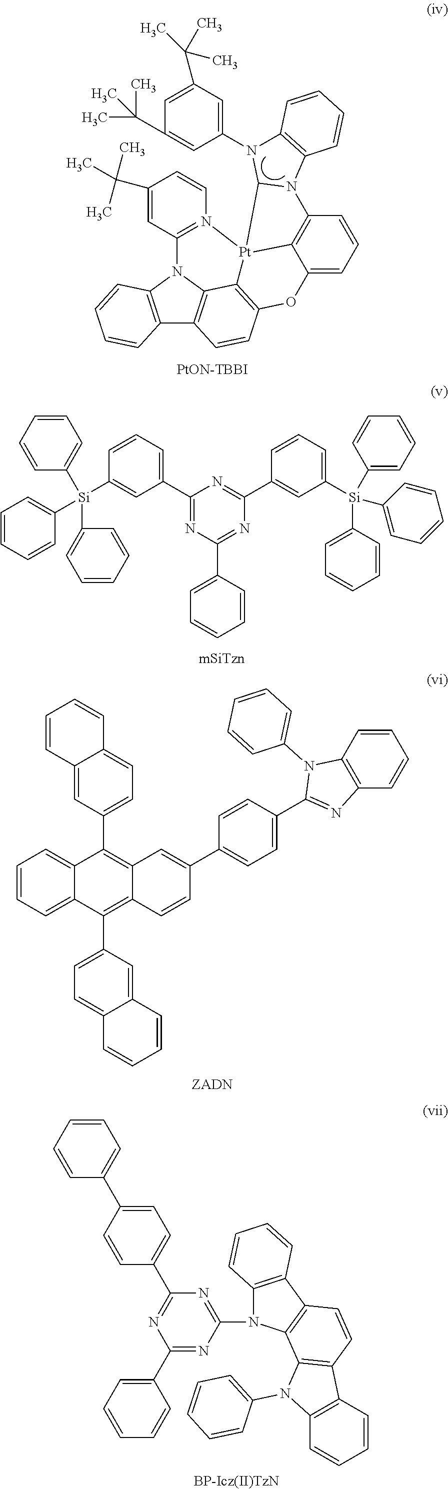

### (Fabrication Method of Light-Emitting Device 1-1)

First, indium tin oxide containing silicon oxide (ITSO) was deposited over a glass substrate to a thickness of 55 nm by a sputtering method, so that the first electrode 101 having a size of 2 mm×2 mm was formed. Note that the ITSO serves as an anode.

Then, pretreatment for formation of the light-emitting device over the substrate was performed by washing the substrate surface with water.

After that, the substrate was transferred into a vacuum evaporation apparatus where the internal pressure was reduced to approximately 1×10⁴ Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited over the inorganic insulating film and the first electrode 101 to a thickness of 10 nm by co-evaporation such that the weight ratio of PCBBiF to OCHD-003 was 1:0.03, whereby the hole-injection layer 111 was formed.

Over the hole-injection layer 111, PCBBiF was deposited by evaporation to a thickness of 45 nm and then, 9-[3-(triphenylsilyl)phenyl]-3,9′-bi-9H-carbazole (abbreviation: PSiCzCz) was deposited by evaporation to a thickness of 5 nm, whereby the hole-transport layer 112 was formed. Note that PSiCzCz is an organic compound having a π-electron rich heteroaromatic ring, and the PSiCzCz layer functions also as an electron-blocking layer.

Next, over the hole-transport layer 112, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, and (2-{3-[3-(3,5-di-tert-butylphenyl)benzimidazol-1-yl-2-ylidene-κC²]phenoxy-κC²}-9-(4-tert-butyl-2-pyridinyl-KN)carbazole-2,1-diyl-κC)platinum(II) (abbreviation: PtON-TBBI) represented by Structural Formula (iv) above were deposited by co-evaporation to a thickness of 40 nm such that the weight ratio of SiTrzCz2 to PSiCzCz to PtON-TBBI was 0.35:0.53:0.12, whereby the light-emitting layer 113 was formed. Note that PtON-TBBI is an organometallic complex that emits blue phosphorescent light. SiTrzCz2 is an organic compound having a π-electron deficient heteroaromatic ring, and PSiCzCz is an organic compound having a π-electron rich heteroaromatic ring.

Then, 2-phenyl-4,6-bis[3-(triphenylsilyl)phenyl]-1,3,5-triazine (abbreviation: mSiTrz) represented by Structural Formula (v) above was deposited by evaporation to a thickness of 5 nm, whereby the first electron-transport layer was formed. After that, 2-{4-[9,10-di(2-naphthyl)-2-anthryl]phenyl}-1-phenyl-1H-benzimidazole (abbreviation: ZADN) and PtON-TBBI were deposited by co-evaporation to a thickness of 30 nm such that the weight ratio of ZADN to PtON-TBBI was 0.9:0.1, whereby the second electron-transport layer was formed. Note that mSiTrz and ZADN are organic compounds each having a π-electron deficient heteroaromatic ring, and the first electron-transport layer functions also as a hole-blocking layer.

After the electron-transport layers were formed, lithium fluoride (abbreviation: LiF) was deposited by evaporation to a thickness of 1 nm to form the electron-injection layer 115, and then aluminum (abbreviation: Al) was deposited by evaporation to a thickness of 200 nm to form the second electrode 102 (cathode).

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under atmospheric pressure for one hour. In this manner, the light-emitting device 1-1 was fabricated.

### (Fabrication Method of Light-Emitting Device 1-2)

The light-emitting device 1-2 was fabricated in the same manner as the light-emitting device 1-1 except that ZADN used for the second electron-transport layer in the light-emitting device 1-1 was replaced with 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn) represented by Structural Formula (vii) above. Note that BP-Icz(II)Tzn is an organic compound having a π-electron deficient heteroaromatic ring.

### (Fabrication Method of Light-Emitting Device 1-3)

The light-emitting device 1-3 was fabricated in the same manner as the light-emitting device 1-1 except that the ZADN used for the second electron-transport layer in the light-emitting device 1-1 was replaced with mSiTrz.

Device structures of the light-emitting devices 1-1, 1-2, and 1-3 are shown in Table 3.

TABLE 3

| | | | |
|---|---|---|---|
| Thickness | Light-emitting | Light-emitting | Light-emitting |
| (nm) | device 1-1 | device 1-2 | device 1-3 |

| | | |
|---|---|---|
| Second electrode | 200 | Al |
| Electron-injection layer | 1 | LiF |
| Second electron-transport layer | 30 | *1:PtON-TBBI |
| | | (0.9:0.1) |
| First electron-transport layer | 5 | mSiTrz |
| Light-emitting layer | 40 | SiTrzCz2:PSiCzCz:PtON-TBBI |
| | | (0.35:0.53:0.12) |
| Hole-transport layer | 5 | PSiCzCz |
| | 45 | PCBBiF |
| Hole-injection layer | 10 | PCBBiF:OCHD-003 (1:0.03) |
| First electrode | 55 | ITSO |

*1Light-emitting device 1-1: ZADN
Light-emitting device 1-2: BP-Icz(II)Tzn
Light-emitting device 1-3: mSiTrz

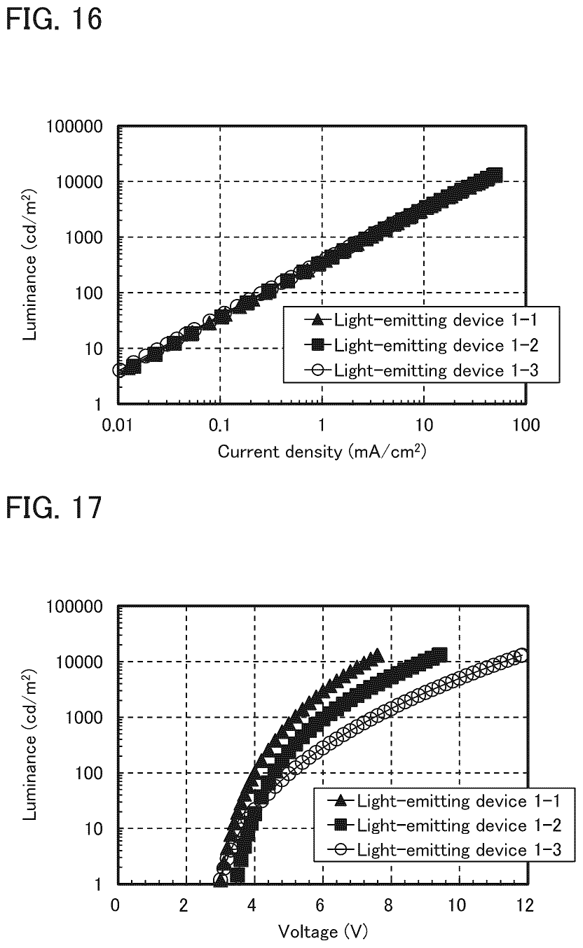

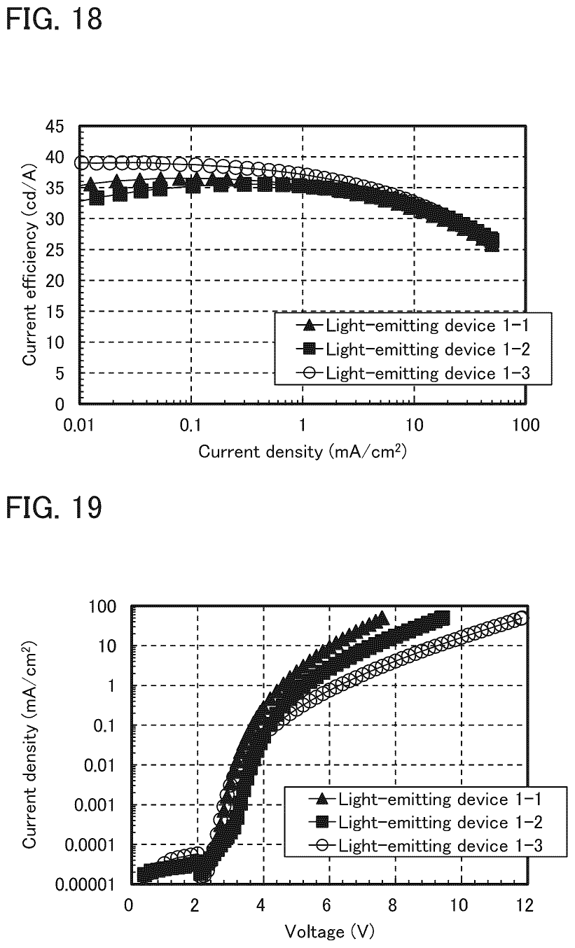

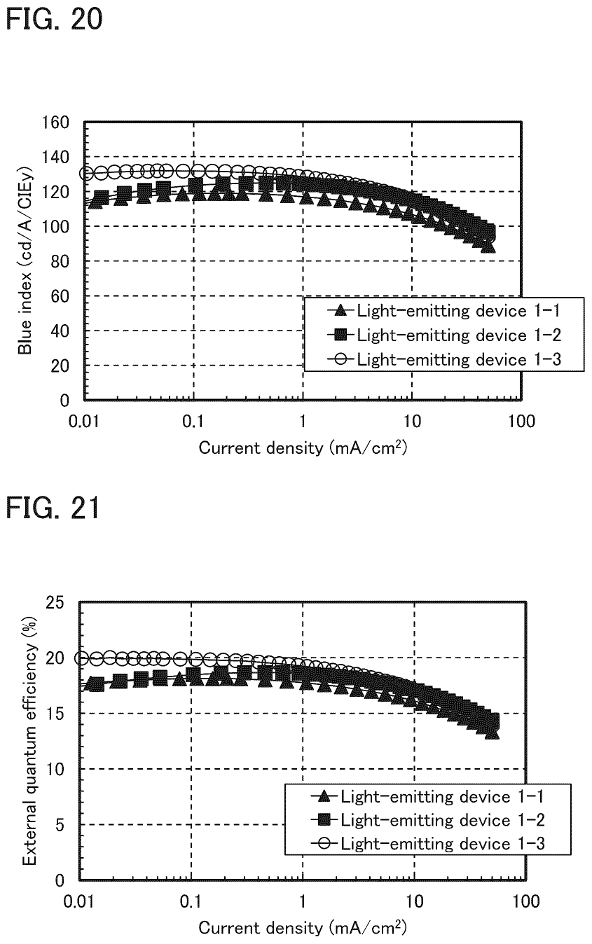

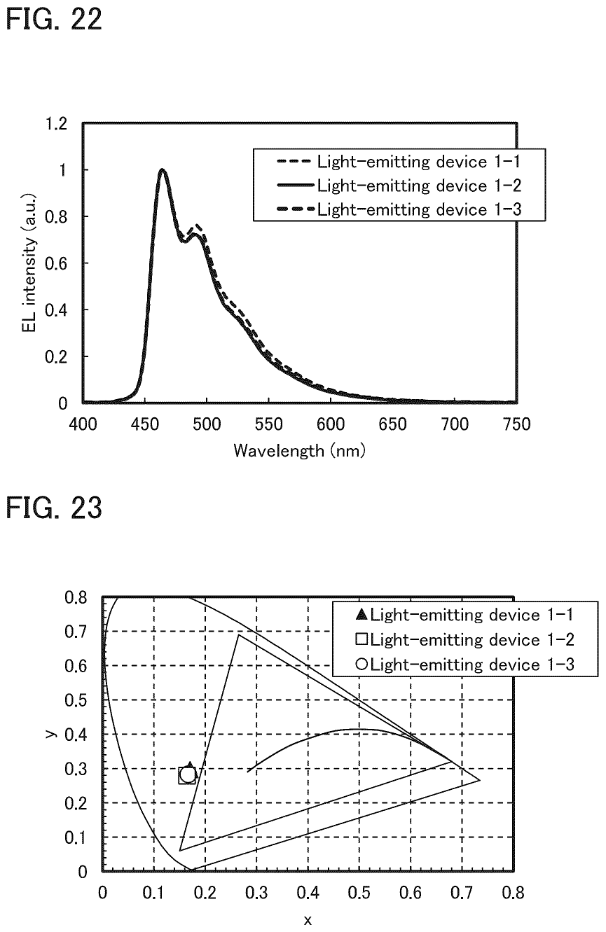

FIG. 16 shows the luminance-current density characteristics of the light-emitting devices 1-1, 1-2, and 1-3. FIG. 17 shows the luminance-voltage characteristics thereof. FIG. 18 shows the current efficiency-current density characteristics thereof. FIG. 19 shows the current density-voltage characteristics thereof. FIG. 20 shows the blue index-current density characteristics thereof. FIG. 21 shows the external quantum efficiency-current density characteristics thereof. FIG. 22 shows the electroluminescence spectra thereof. FIG. 23 shows the chromaticity diagram thereof. Table 4 shows the main characteristics of the light-emitting devices at a current density of 10 mA/cm². The luminance, CIE chromaticity, and electroluminescence spectra were measured at normal temperature with a spectroradiometer (SR-UL1R produced by TOPCON TECHNOHOUSE CORPORATION). The external quantum efficiency was calculated from the measured luminance and emission spectrum, on the assumption that the light-emitting device had Lambertian light-distribution characteristics.

TABLE 4

| | | | | | | | | External |
|---|---|---|---|---|---|---|---|---|
| | | | Chroma- | Chroma- | Current | BI | Power | quantum |
| | Voltage | Luminance | ticity | ticity | efficiency | (cd/A/ | efficiency | efficiency |
| | (V) | (cd/m²) | x | y | (cd/A) | CIEy) | (lm/W) | (%) |
| Light-emitting | 6.06 | 3160 | 0.171 | 0.296 | 31.7 | 107 | 16.4 | 16.1 |
| device 1-1 | | | | | | | | |
| Light-emitting | 7.33 | 3210 | 0.164 | 0.279 | 32.1 | 115 | 13.8 | 17.1 |
| device 1-2 | | | | | | | | |
| Light-emitting | 9.26 | 3260 | 0.167 | 0.283 | 32.6 | 115 | 11.1 | 17.1 |
| device 1-3 | | | | | | | | |

The above results reveal that the light-emitting devices 1-1 and 1-2 each have a low driving voltage and a high power efficiency.

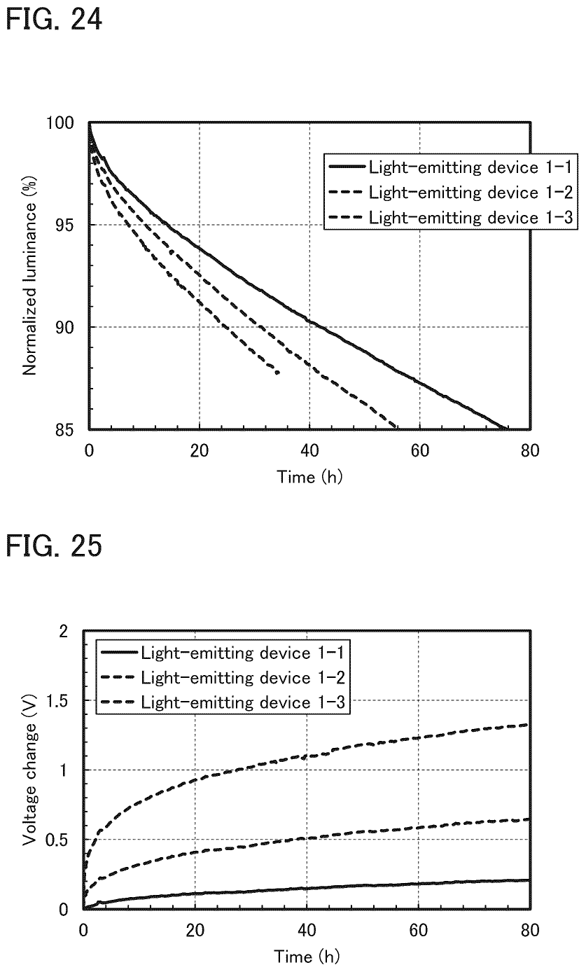

FIG. 24 and FIG. 25 show the time dependence of normalized luminances of the light-emitting devices 1-1, 1-2, and 1-3 driven at a current density of 10 mA/cm² and the time dependence of voltages thereof, respectively. Note that the time dependence of normalized luminances is shown assuming the initial luminances to be 100%, and the time dependence of voltages is shown as voltage changes from the initial voltages.

FIGS. 24 and 25 reveal that the light-emitting devices 1-1 and 1-2 each have high reliability with a small decrease in luminance and a small increase in voltage over driving time.

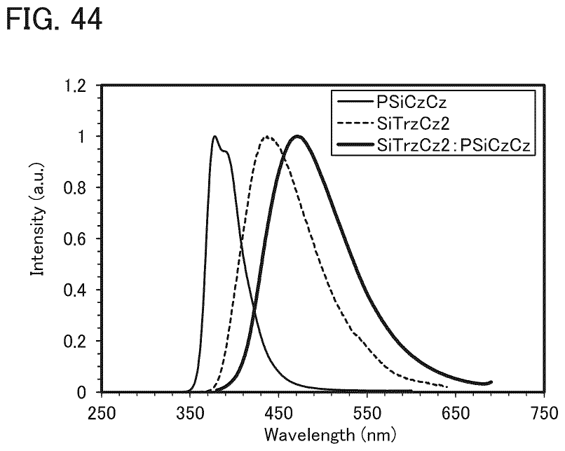

FIG. 44 shows the emission spectra (PL spectra) of a film of SiTrzCz2, a film of PSiCzCz, and a mixed film of SiTrzCz2 and PSiCzCz with a weight ratio of 1:1. Note that the emission spectra were measured at room temperature using sample films each deposited by evaporation to a thickness of 50 nm over a quartz substrate. A fluorescence spectrophotometer (FP-8600 manufactured by JASCO Corporation) was used for the measurement. The wavelength of excitation light was set to 330 nm (for the film of SiTrzCz2), 310 nm (for the film of PSiCzCz), and 355 nm (for the mixed film of SiTrzCz2 and PSiCzCz). As shown in FIG. 44, the emission spectrum of the mixed film is positioned on the longer wavelength side than the emission spectra of the films of the single materials, indicating that SiTrzCz2 and PSiCzCz form an exciplex. In other words, a combination of SiTrzCz2 and PSiCzCz forms an exciplex.

Table 5 shows the GSP_Slopes of evaporated films of the organic compound having a π-electron rich heteroaromatic ring or an aromatic amine which was used for the hole-transport layers of the light-emitting devices 1-1, 1-2, and 1-3, the organic compound having a π-electron deficient heteroaromatic ring which was used for the first electron-transport layers thereof, the organic compounds each having a π-electron deficient heteroaromatic ring which were used for the second electron-transport layers thereof, and the host materials used for the light-emitting layers thereof. Table 5 also shows the GSP_Slope of a film formed by co-evaporation of SiTrzCz2, PSiCzCz, and PtON-TBBI, which are the components of the light-emitting layer, at a weight ratio of SiTrzCz2 to PSiCzCz to PtON-TBBI of 0.45:0.45:0.10. Note that the GSP_Slopes in Table 5 were measured by the method described in Embodiment 1.

TABLE 5

| Abbreviation of material and | GSP_Slope |
|---|---|
| composition of evaporated film | (mV/nm) |
| mSiTrz | 10.3 |
| ZADN | 84.7 |
| BP-Icz(II)Tzn | 92.1 |
| SiTrzCz2 | 22.4 |
| PSiCzCz | 34.7 |
| SiTrzCz2:PSiCzCz:PtON-TBBI | 73.3 |
| (0.45:0.45:0.10) | |

The above results reveal that, in each of the light-emitting devices 1-1 and 1-2, the GSP_Slope of the film of the organic compound having a π-electron deficient heteroaromatic ring in the second electron-transport layer is larger than the GSP_Slope of the film of the organic compound having a π-electron deficient heteroaromatic ring in the first electron-transport layer. In the light-emitting device 1-3, the GSP_Slope of the film of the organic compound having a π-electron deficient heteroaromatic ring in the second electron-transport layer is equal to the GSP_Slope of the film of the organic compound having a π-electron deficient heteroaromatic ring in the first electron-transport layer.

Thus, in each of the light-emitting devices 1-1 and 1-2, a negative interface charge due to a difference in GSP_Slope is provided at the interface between the first electron-transport layer and the second electron-transport layer. This inhibits electron injection from the second electrode or the electron-injection layer into the second electron-transport layer. As a result, a recombination region that normally tends to deviate to the anode side in the light-emitting layer of a blue phosphorescent device can be expanded, so that degradation of the hole-transport layer functioning as an electron-blocking layer can be reduced. Accordingly, the light-emitting devices 1-1 and 1-2 have high reliability.

Note that in each of the above light-emitting devices, the GSP_Slope of the film of each of the host materials (SiTrzCz2 and PSiCzCz) is larger than the GSP_Slope of the film of the first organic compound (mSiTrz). The GSP_Slope of the light-emitting layer is larger than the GSP_Slope of the first electron-transport layer.

With this structure, electrons are smoothly injected from the second electron-transport layer into the first electron-transport layer in each of the above light-emitting devices. Accordingly, the light-emitting devices 1-1 and 1-2 can have favorable characteristics without causing a significant increase in driving voltage even when electron injection from the second electrode or the electron-injection layer into the second electron-transport layer is inhibited.

Furthermore, ZADN and BP-Icz(II)Tzn, which are the organic compounds each having a π-electron deficient heteroaromatic ring in the second electron-transport layers of the light-emitting devices 1-1 and 1-2, each have a larger GSP_Slope than the host materials (SiTrzCz2 and PSiCzCz) in a film state. In addition, the GSP_Slope of the second electron-transport layer is larger than the GSP_Slope of the light-emitting layer.

Accordingly, in each of the light-emitting devices 1-1 and 1-2, the charge at the interface between the first electron-transport layer and the second electron-transport layer is negative and smaller than the charge at the interface between the light-emitting layer and the first electron-transport layer. This inhibits electron injection from the second electrode or the electron-injection layer into the second electron-transport layer. It also promotes hole injection into the light-emitting layer. As a result, the recombination region that normally tends to deviate to the anode side in the light-emitting layer of the blue phosphorescent device can be expanded, so that degradation of the hole-transport layer functioning as an electron-blocking layer can be further reduced.

In each of the above light-emitting devices, the GSP_Slope of the light-emitting layer (the co-evaporated film of SiTrzCz2, PSiCzCz, and PtON-TBBI) is larger than the GSP_Slope of the hole-transport layer (the evaporated film of PSiCzCz). This facilitates hole injection from the hole-injection layer into the hole-transport layer and thus enables the light-emitting device to have a low driving voltage.

As described above, each of the light-emitting devices of one embodiment of the present invention can have high reliability, a low driving voltage, and favorable characteristics.

### Example 2

Described in this example are specific methods for fabricating a light-emitting device 2-1a, a light-emitting device 2-1b, a light-emitting device 2-2a, and a light-emitting device 2-2b of embodiments of the present invention and a comparative light-emitting device 2-1, a comparative light-emitting device 2-2a, and a comparative light-emitting device 2-2b of comparative examples and characteristics of the light-emitting devices. Structural formulae of main compounds used in this example are shown below.

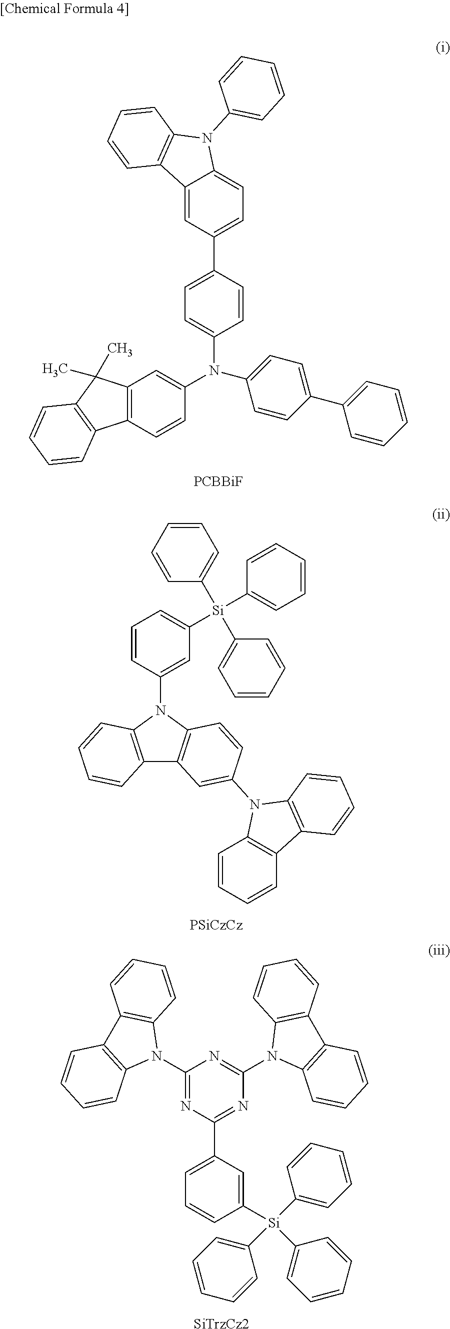

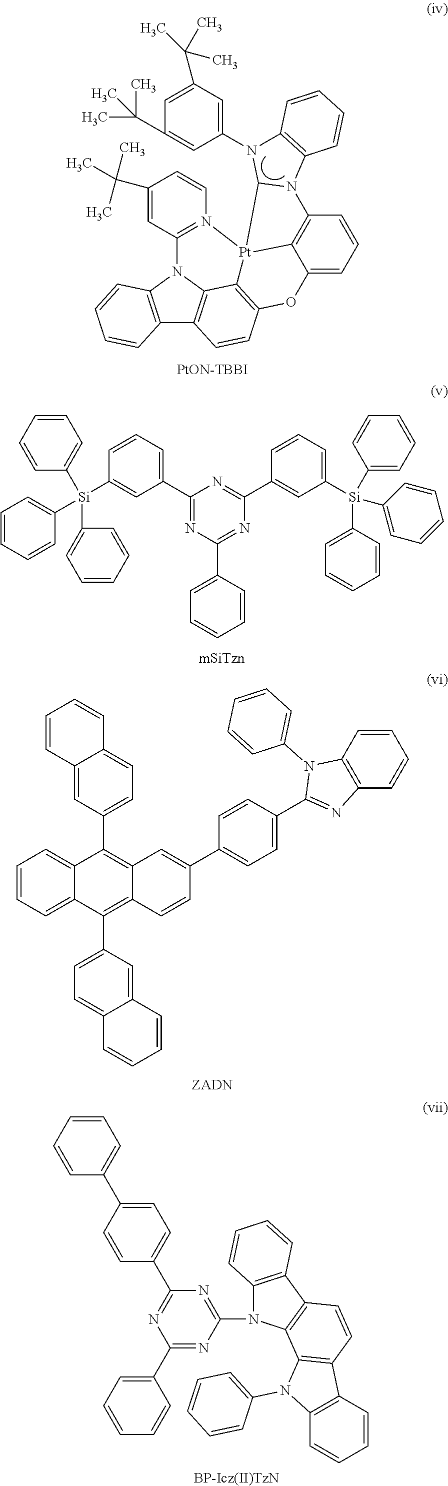

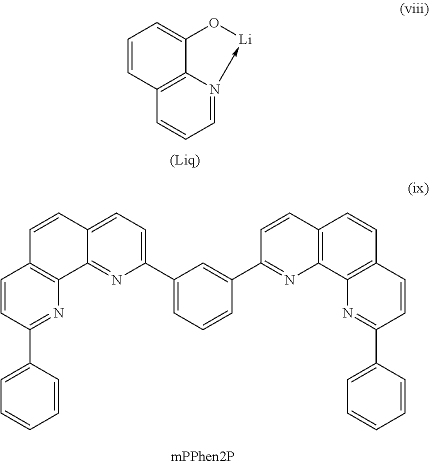

### (Fabrication Method of Light-Emitting Device 2-1a)

First, indium tin oxide containing silicon oxide (ITSO) was deposited over a glass substrate to a thickness of 55 nm by a sputtering method, so that the first electrode 101 having a size of 2 mm×2 mm was formed. Note that the ITSO serves as an anode.

Then, pretreatment for formation of the light-emitting device over the substrate was performed by washing the substrate surface with water.

After that, the substrate was transferred into a vacuum evaporation apparatus where the internal pressure was reduced to approximately 1×10-4 Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited over the inorganic insulating film and the first electrode 101 to a thickness of 10 nm by co-evaporation such that the weight ratio of PCBBiF to OCHD-003 was 1:0.03, whereby the hole-injection layer 111 was formed.

Over the hole-injection layer 111, PCBBiF was deposited by evaporation to a thickness of 45 nm and then, 9-[3-(triphenylsilyl)phenyl]-3,9′-bi-9H-carbazole (abbreviation: PSiCzCz) was deposited by evaporation to a thickness of 5 nm, whereby the hole-transport layer 112 was formed. Note that PSiCzCz is an organic compound having a π-electron rich heteroaromatic ring, and the PSiCzCz layer functions also as an electron-blocking layer.

Next, over the hole-transport layer 112, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, and (2-{3-[3-(3,5-di-tert-butylphenyl)benzimidazol-1-yl-2-ylidene-κC²]phenoxy-κC²}-9-(4-tert-butyl-2-pyridinyl-KN)carbazole-2,1-diyl-κC)platinum(II) (abbreviation: PtON-TBBI) represented by Structural Formula (iv) above were deposited by co-evaporation to a thickness of 40 nm such that the weight ratio of SiTrzCz2 to PSiCzCz to PtON-TBBI was 0.35:0.53:0.12, whereby the light-emitting layer 113 was formed. Note that PtON-TBBI is an organometallic complex that emits blue phosphorescent light (whose emission spectrum has a peak wavelength greater than or equal to 450 nm and less than or equal to 520 nm). SiTrzCz2 is an organic compound having a π-electron deficient heteroaromatic ring, and PSiCzCz is an organic compound having a π-electron rich heteroaromatic ring.

Then, 2-phenyl-4,6-bis[3-(triphenylsilyl)phenyl]-1,3,5-triazine (abbreviation: mSiTrz) represented by Structural Formula (v) above was deposited by evaporation to a thickness of 5 nm, whereby the first electron-transport layer was formed. After that, 2-{4-[9,10-di(2-naphthyl)-2-anthryl]phenyl}-1-phenyl-1H-benzimidazole (abbreviation: ZADN) represented by Structural Formula (vi) above and 8-quinolinolato-lithium (abbreviation: Liq) represented by Structural Formula (viii) above were deposited by co-evaporation to a thickness of 30 nm such that the weight ratio of ZADN to Liq was 1:1, whereby the second electron-transport layer was formed. Note that mSiTrz and ZADN are organic compounds each having a π-electron deficient heteroaromatic ring, Liq is an organometallic complex including an alkali metal, and the first electron-transport layer functions also as a hole-blocking layer.

After the electron-transport layers were formed, lithium fluoride (abbreviation: LiF) was deposited by evaporation to a thickness of 1 nm to form the electron-injection layer 115, and then aluminum (abbreviation: Al) was deposited by evaporation to a thickness of 200 nm to form the second electrode 102 (cathode).

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under atmospheric pressure for one hour. In this manner, the light-emitting device 2-1a was fabricated.

### (Fabrication Method of Light-Emitting Device 2-1b)

The light-emitting device 2-1b was fabricated in the same manner as the light-emitting device 2-1a except that the second electron-transport layer in the light-emitting device 2-1b was deposited by co-evaporation of ZADN and Liq at a weight ratio of 1:4 (=ZADN:Liq).

### (Fabrication Method of Light-Emitting Device 2-2a)

The light-emitting device 2-2a was fabricated in the same manner as the light-emitting device 2-1a except that ZADN used for the second electron-transport layer in the light-emitting device 2-1a was replaced with 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn) represented by Structural Formula (vii) above. Note that BP-Icz(II)Tzn is an organic compound having a π-electron deficient heteroaromatic ring.

### (Fabrication Method of Light-Emitting Device 2-2b)

The light-emitting device 2-2b was fabricated in the same manner as the light-emitting device 2-1b except that ZADN used for the second electron-transport layer in the light-emitting device 2-1b was replaced with BP-Icz(II)Tzn.

### (Fabrication Method of Comparative Light-Emitting Device 2-1)

The comparative light-emitting device 2-1 was fabricated in the same manner as the light-emitting device 2-1a except that the second electron-transport layer in the comparative light-emitting device 2-1 was formed using 2,2′-(1,3-phenylene)bis(9-phenyl-1,10-phenanthroline) (abbreviation: mPPhen2P) represented by Structural Formula (ix) above.

### (Fabrication Method of Comparative Light-Emitting Device 2-2a)

The comparative light-emitting device 2-2a was fabricated in the same manner as the light-emitting device 2-1a except that ZADN used for the second electron-transport layer in the light-emitting device 2-1a was replaced with mSiTrz.

### (Fabrication Method of Comparative Light-Emitting Device 2-2b)

The comparative light-emitting device 2-2b was fabricated in the same manner as the light-emitting device 2-1b except that ZADN used for the second electron-transport layer in the light-emitting device 2-1b was replaced with mSiTrz.

Device structures of the light-emitting devices 2-1a, 2-1b, 2-2a, and 2-2b and the comparative light-emitting devices 2-1, 2-2a, and 2-2b are shown in Tables 6 and 7.

TABLE 6

| Thickness | Light-emitting device | | | | Comparative light-emitting device | | |
|---|---|---|---|---|---|---|---|
| (nm) | 2-1a | 2-1b | 2-2a | 2-2b | 2-1 | 2-2a | 2-2b |

| | | |
|---|---|---|
| Second electrode | 200 | Al |
| Electron-injection layer | 1 | LiF |
| Electron-transport layer | 30 | *2 |
| | 5 | mSiTrz |
| Light-emitting layer | 40 | SiTrzCz2:PSiCzCz:PtON-TBBI |
| | | (0.35:0.53:0.12) |
| Hole-transport layer | 5 | PSiCzCz |
| | 45 | PCBBiF |
| Hole-injection layer | 10 | PCBBiF:OCHD-003 (1:0.03) |
| First electrode | 55 | ITSO |

TABLE 7

| | | *2 |
|---|---|---|
| Light- | 2-1a | ZADN:Liq (1:1) |
| emitting | 2-1b | ZADN:Liq (1:4) |
| device | 2-2a | BP-Icz(II)Tzn:Liq (1:1) |
| | 2-2b | BP-Icz(II)Tzn:Liq (1:4) |
| Comparative | 2-1 | mPPhen2P |
| light-emitting | 2-2a | mSiTrz:Liq (1:1) |
| device | 2-2b | mSiTrz:Liq (1:4) |

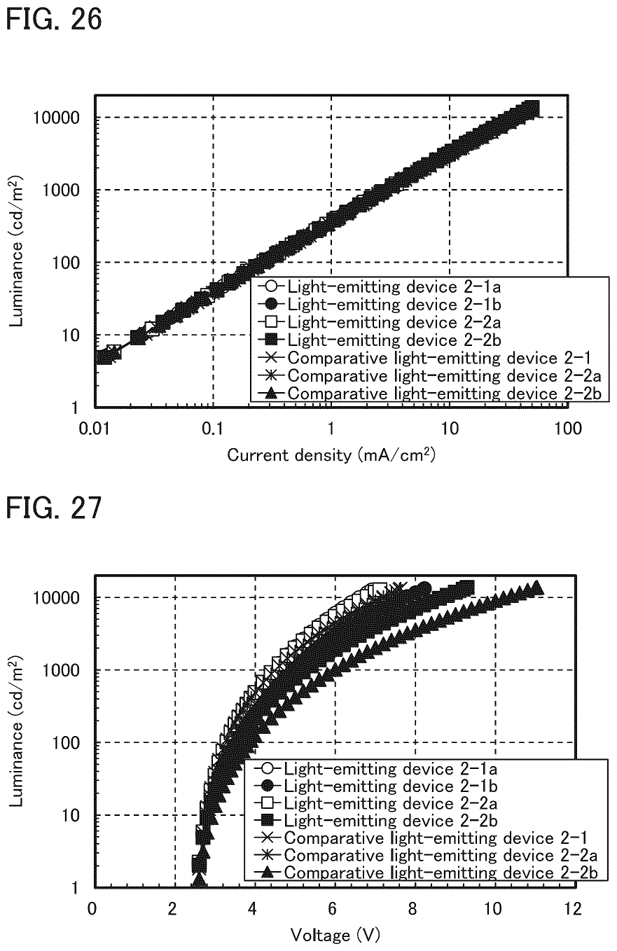

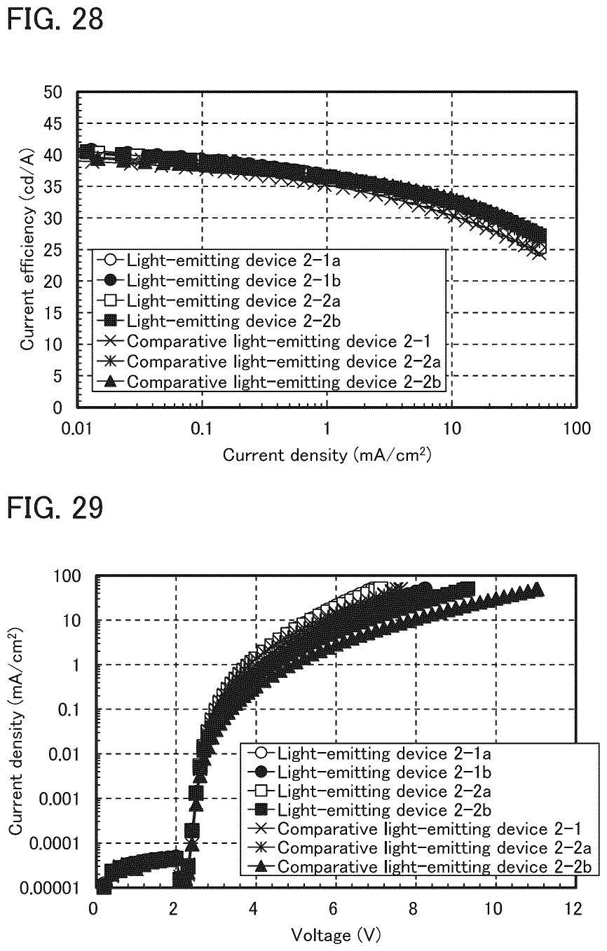

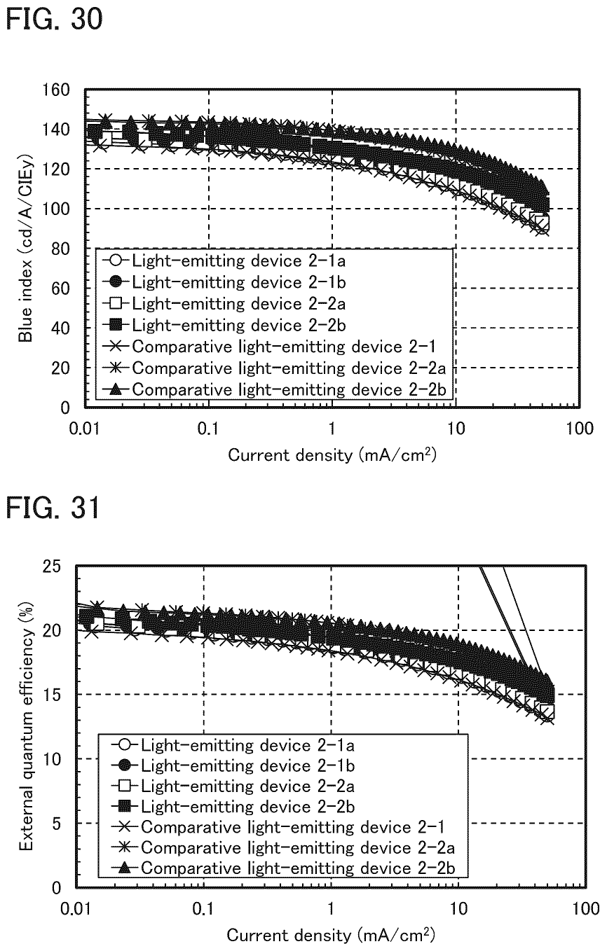

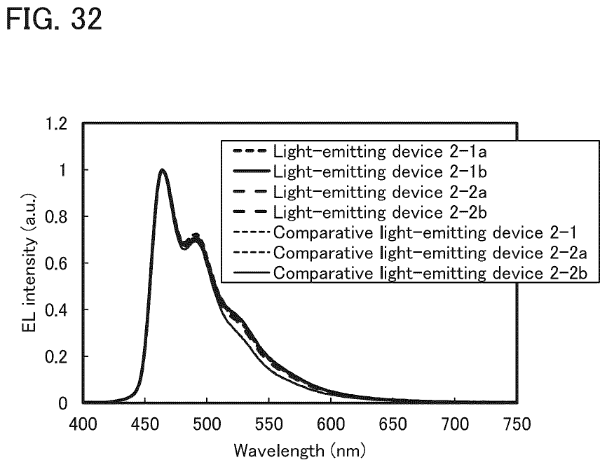

FIG. 26 shows the luminance-current density characteristics of the light-emitting devices 2-1a, 2-1b, 2-2a, and 2-2b and the comparative light-emitting devices 2-1, 2-2a, and 2-2b. FIG. 27 shows the luminance-voltage characteristics thereof. FIG. 28 shows the current efficiency-current density characteristics thereof. FIG. 29 shows the current density-voltage characteristics thereof. FIG. 30 shows the blue index-current density characteristics thereof. FIG. 31 shows the external quantum efficiency-current density characteristics thereof. FIG. 32 shows the electroluminescence spectra thereof. Table 8 shows the main characteristics of the light-emitting devices at a current density of 10 mA/cm². The luminance, CIE chromaticity, and electroluminescence spectra were measured at normal temperature with a spectroradiometer (SR-UL1R produced by TOPCON TECHNOHOUSE CORPORATION). The external quantum efficiency was calculated from the measured luminance and emission spectrum, on the assumption that the light-emitting device had Lambertian light-distribution characteristics.

TABLE 8

| | | | | | | | | | External |
|---|---|---|---|---|---|---|---|---|---|
| | | | | Chroma- | Chroma- | Current | BI | Power | quantum |
| | | Voltage | Luminance | ticity | ticity | efficiency | (cd/A/ | efficiency | efficiency |
| | | (V) | (cd/m²) | x | y | (cd/A) | CIEy) | (lm/W) | (%) |
| Light- | 2-1a | 5.34 | 3130 | 0.166 | 0.283 | 31.4 | 111 | 18.4 | 16.5 |
| emitting | 2-1b | 6.10 | 3200 | 0.167 | 0.283 | 32.0 | 113 | 16.5 | 16.8 |
| device | 2-2a | 5.42 | 3160 | 0.166 | 0.281 | 31.6 | 112 | 18.3 | 16.7 |
| | 2-2b | 6.73 | 3250 | 0.163 | 0.273 | 32.5 | 119 | 15.2 | 17.6 |
| Comparative | 2-1 | 5.75 | 3040 | 0.165 | 0.279 | 30.4 | 109 | 16.6 | 16.1 |
| light- | 2-2a | 5.61 | 3230 | 0.156 | 0.256 | 32.3 | 126 | 18.1 | 18.4 |
| emitting | 2-2b | 7.85 | 3310 | 0.156 | 0.256 | 33.1 | 129 | 13.2 | 18.9 |
| device | | | | | | | | | |

The above results reveal that the light-emitting devices 2-1a, 2-1b, 2-2a, and 2-2b and the comparative light-emitting devices 2-1, 2-2a, and 2-2b each have favorable characteristics.

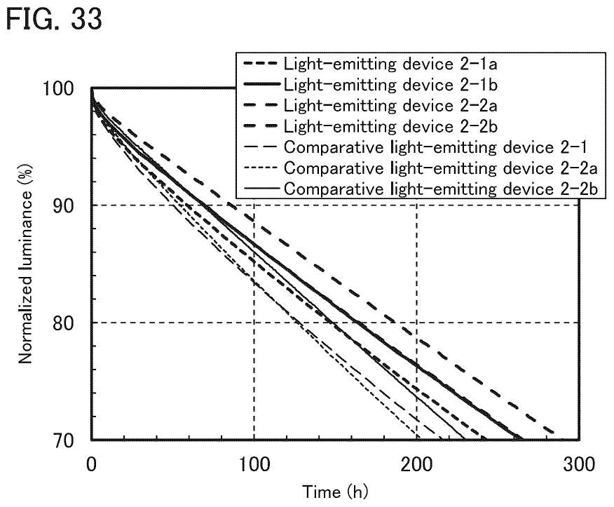

FIG. 33 shows the time dependence of normalized luminances of the light-emitting devices 2-1a, 2-1b, 2-2a, and 2-2b and the comparative light-emitting devices 2-1, 2-2a, and 2-2b driven at a current density of 10 mA/cm². Note that the time dependence of normalized luminances is shown assuming the initial luminances to be 100%.

FIG. 33 reveals that the light-emitting devices 2-1a, 2-1b, 2-2a, and 2-2b each have high reliability with a smaller decrease in luminance over driving time than that of each of the comparative light-emitting devices 2-1, 2-2a, and 2-2b.

FIG. 44 shows the emission spectra (PL spectra) of a film of SiTrzCz2, a film of PSiCzCz, and a mixed film of SiTrzCz2 and PSiCzCz with a weight ratio of 1:1. Note that the emission spectra were measured at room temperature using sample films each deposited by evaporation to a thickness of 50 nm over a quartz substrate. A fluorescence spectrophotometer (FP-8600 manufactured by JASCO Corporation) was used for the measurement. The wavelength of excitation light was set to 330 nm (for the film of SiTrzCz2), 310 nm (for the film of PSiCzCz), and 355 nm (for the mixed film of SiTrzCz2 and PSiCzCz). As shown in FIG. 44, the emission spectrum of the mixed film is positioned on the longer wavelength side than the emission spectra of the films of the single materials, indicating that SiTrzCz2 and PSiCzCz form an exciplex. In other words, a combination of SiTrzCz2 and PSiCzCz forms an exciplex.

Here, Table 9 shows the GSP_Slopes of evaporated films of the organic compound having a π-electron deficient heteroaromatic ring which was used for the first electron-transport layers of the light-emitting devices 2-1a, 2-1b, 2-2a, and 2-2b and the comparative light-emitting devices 2-1, 2-2a, and 2-2b, the organic compounds each having a π-electron deficient heteroaromatic ring which were used for the second electron-transport layers thereof, the organic compound having a π-electron rich heteroaromatic ring or an aromatic amine which was used for the hole-transport layers thereof, and the host materials used for the light-emitting layers thereof. Table 9 also shows the GSP_Slope of a film formed by co-evaporation of SiTrzCz2, PSiCzCz, and PtON-TBBI, which are the components of the light-emitting layer, at a weight ratio of SiTrzCz2 to PSiCzCz to PtON-TBBI of 0.45:0.45:0.10. Note that the GSP_Slopes in Table 9 were measured by the method described in Embodiment 1.

TABLE 9

| Abbreviation of material and | GSP_Slope |
|---|---|
| composition of evaporated film | (mV/nm) |
| mSiTrz | 10.3 |
| ZADN | 84.7 |
| BP-Icz(II)Tzn | 92.1 |
| mPPhen2P | 1.50 |
| SiTrzCz2 | 22.4 |
| PSiCzCz | 34.7 |
| SiTrzCz2:PSiCzCz:PtON-TBBI | 73.3 |
| (0.45:0.45:0.10) | |

The above results reveal that, in each of the light-emitting devices 2-1a, 2-1b, 2-2a, and 2-2b, the GSP_Slope of the film of the organic compound having a π-electron deficient heteroaromatic ring in the second electron-transport layer is larger than the GSP_Slope of the film of the organic compound having a π-electron deficient heteroaromatic ring in the first electron-transport layer.

Meanwhile, in the comparative light-emitting device 2-1, the GSP_Slope of the film of the organic compound having a π-electron deficient heteroaromatic ring in the second electron-transport layer is smaller than the GSP_Slope of the film of the organic compound having a it-electron deficient heteroaromatic ring in the first electron-transport layer. In each of the comparative light-emitting devices 2-2a and 2-2b, the GSP_Slope of the film of the organic compound having a π-electron deficient heteroaromatic ring in the second electron-transport layer is equal to the GSP_Slope of the film of the organic compound having a π-electron deficient heteroaromatic ring in the first electron-transport layer.

Here, the capacitance-voltage characteristics of a light-emitting device of one embodiment of the present invention (a light-emitting device 2) and a light-emitting device of a comparative example (a comparative light-emitting device 2) were measured for examination of their carrier injection behavior. The light-emitting device 2 has a structure similar to that of the light-emitting device 2-2b, and the comparative light-emitting device 2 has a structure similar to that of the comparative light-emitting device 2-1a. Note that the capacitance-voltage characteristics were measured at room temperature at a frequency of 10 Hz with a potentiostat/galvanostat (SP-300 manufactured by BioLogic Science Instruments SAS (France)).

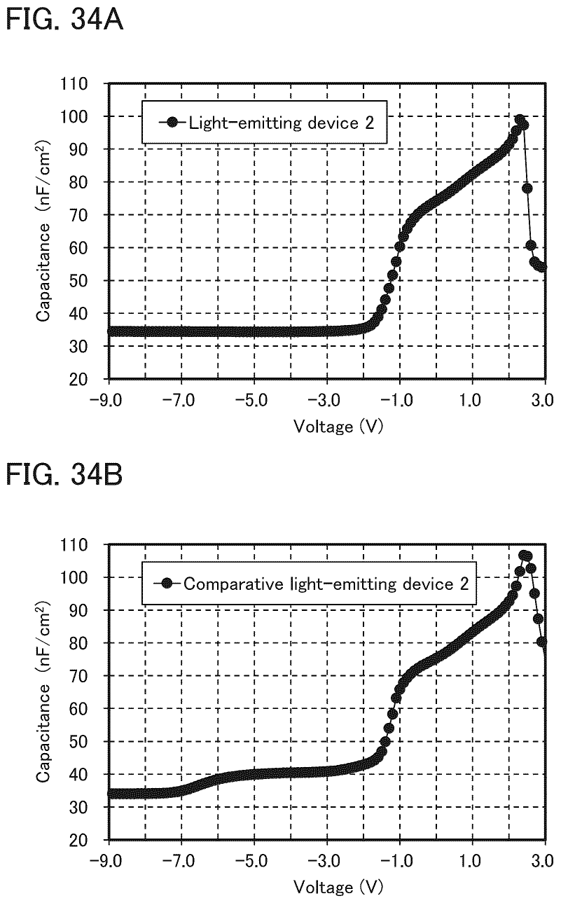

FIG. 34B shows the measurement results of the comparative light-emitting device 2. FIG. 34B reveals that electrons startto be injected from the electron-injection layer into the second electron-transport layer at approximately −7.0 V and from the second electron-transport layer into the first electron-transport layer at approximately −3.0 V.

FIG. 34A shows the measurement results of the light-emitting device 2. FIG. 34A reveals that electrons start to be injected from the electron-injection layer into the second electron-transport layer at approximately −1.0 V and from the second electron-transport layer into the first electron-transport layer at approximately 0 V.

These results indicate that electron injection is inhibited in each of the light-emitting devices of one embodiment of the present invention.

In this manner, electron injection into the second electron-transport layer is further inhibited in each of the light-emitting devices 2-1a, 2-1b, 2-2a, and 2-2b. In the light-emitting layer of the general blue phosphorescent device, the blue phosphorescent light-emitting substance, whose HOMO level and LUMO level are both higher than those of the host material, traps holes but not electrons; thus, the recombination region tends to deviate to the anode side. In the light-emitting device of one embodiment of the present invention, electron injection into the second electron-transport layer is inhibited owing to the above-described structure; thus, the recombination region that tends to deviate to the anode side can be expanded, so that degradation of the hole-transport layer functioning as an electron-blocking layer can be reduced. This improves the reliability of the light-emitting devices 2-1a, 2-1b, 2-2a, and 2-2b. Note that PSiCzCz used as the host material in the light-emitting layer in this example has a HOMO level of −5.7 eV and a LUMO level of −2.06 eV; SiTrzCz2 used as the host material in the light-emitting layer in this example has a HOMO level lower than that of PSiCzCz and a LUMO level of −2.98 eV; and PtON-TBBI used as the blue phosphorescent light-emitting substance has a HOMO level of −5.50 eV and a LUMO level of −2.3 eV and thus traps holes but not electrons as described above.

The values of the HOMO levels and the LUMO levels were obtained through a cyclic voltammetry (CV) measurement.

In the cyclic voltammetry (CV) measurement, the values (E) of the HOMO and LUMO levels were calculated on the basis of an oxidation peak potential (Eₚₐ) and a reduction peak potential (E_{pc}), which were obtained by changing the potential of a working electrode with respect to a reference electrode. In the measurement, a HOMO level and a LUMO level were obtained by potential scanning in the positive direction and potential scanning in the negative direction, respectively. The scanning speed in the measurement was 0.1 V/s.

Specifically, a standard oxidation-reduction potential (Eₒ) (=Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby each of the values (E)(=Eₓ−Eₒ) of HOMO and LUMO levels was obtained.

Note that the reversible oxidation-reduction wave was obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

In each of the light-emitting devices 2-1a, 2-1b, 2-2a, and 2-2b and each of the comparative light-emitting devices 2-2a and 2-2b, the second electron-transport layer contains Liq, which is a metal complex including an alkali metal, in addition to the organic compound having a π-electron deficient heteroaromatic ring. When the weight ratio of the organic compound having a π-electron deficient heteroaromatic ring to Liq in the second electron-transport layer is x:y, a value of (x+y)/x times the GSP_Slope of the film of the organic compound having a π-electron deficient heteroaromatic ring in the first electron-transport layer is 20.6 (mV/nm) for the light-emitting devices 2-1a and 2-2a and the comparative light-emitting device 2-2a and 51.5 (mV/nm) for the light-emitting devices 2-1b and 2-2b and the comparative light-emitting device 2-2b. The GSP_Slope of the film of the organic compound having a π-electron deficient heteroaromatic ring in the second electron-transport layer is larger than (x+y)/x times the GSP_Slope of the film of the organic compound having a π-electron deficient heteroaromatic ring in the first electron-transport layer in each of the light-emitting devices 2-1a, 2-1b, 2-2a, and 2-2b, and is equal to or smaller than the GSP_Slope of the film of the organic compound having a π-electron deficient heteroaromatic ring in the first electron-transport layer in each of the comparative light-emitting devices 2-2a and 2-2b.

As described above, when the weight ratio of the organic compound having a π-electron deficient heteroaromatic ring to Liq in the second electron-transport layer is x:y and the GSP_Slope of the film of the organic compound having a π-electron deficient heteroaromatic ring in the second electron-transport layer is larger than (x+y)/x times the GSP_Slope of the film of the organic compound having a π-electron deficient heteroaromatic ring in the first electron-transport layer, electron injection from the second electrode or the electron-injection layer into the second electron-transport layer can be inhibited, so that the light-emitting device can have high reliability.

Note that in each of the above light-emitting devices, the GSP_Slope of the film of each of the host materials (SiTrzCz2 and PSiCzCz) is larger than the GSP_Slope of the film of the first organic compound. The GSP_Slope of the light-emitting layer is larger than the GSP_Slope of the first electron-transport layer.

With this structure, a positive interface charge can be provided at the interface between the light-emitting layer and the first electron-transport layer; thus, electrons are injected smoothly from the second electron-transport layer into the first electron-transport layer in each of the above light-emitting devices. Accordingly, the light-emitting devices 2-1a, 2-1b, 2-2a, and 2-2b can have favorable characteristics without causing a significant increase in driving voltage even when electron injection into the second electron-transport layer is inhibited.

Furthermore, ZADN and BP-Icz(II)Tzn, which are the organic compounds each having a π-electron deficient heteroaromatic ring in the second electron-transport layers of the light-emitting devices 2-1a, 2-1b, 2-2a, and 2-2b, each have a larger GSP_Slope than the host materials (SiTrzCz2 and PSiCzCz) in a film state. In addition, the GSP_Slope of the second electron-transport layer is larger than the GSP_Slope of the light-emitting layer.

Accordingly, in each of the light-emitting devices 2-1a, 2-1b, 2-2a, and 2-2b, the charge at the interface between the first electron-transport layer and the second electron-transport layer is negative and smaller than the charge at the interface between the light-emitting layer and the first electron-transport layer. This inhibits electron injection from the second electrode or the electron-injection layer into the second electron-transport layer. It also promotes hole injection into the light-emitting layer. As a result, the recombination region that normally tends to deviate to the anode side in the light-emitting layer of the blue phosphorescent device can be expanded, so that degradation of the hole-transport layer functioning as an electron-blocking layer can be further reduced.

In each of the above light-emitting devices, the GSP_Slope of the light-emitting layer (the co-evaporated film of SiTrzCz2, PSiCzCz, and PtON-TBBI) is larger than the GSP_Slope of the hole-transport layer (the evaporated film of PSiCzCz). This facilitates hole injection from the hole-transport layer into the light-emitting layer and thus enables the light-emitting device to have a low driving voltage.

As described above, each of the light-emitting devices of one embodiment of the present invention can have high reliability and favorable characteristics.

### Example 3

Described in this example are specific methods for fabricating a light-emitting device 3 of one embodiment of the present invention and a comparative light-emitting device 3 of a comparative example and characteristics of the light-emitting devices. Structural formulae of main compounds used in this example are shown below.

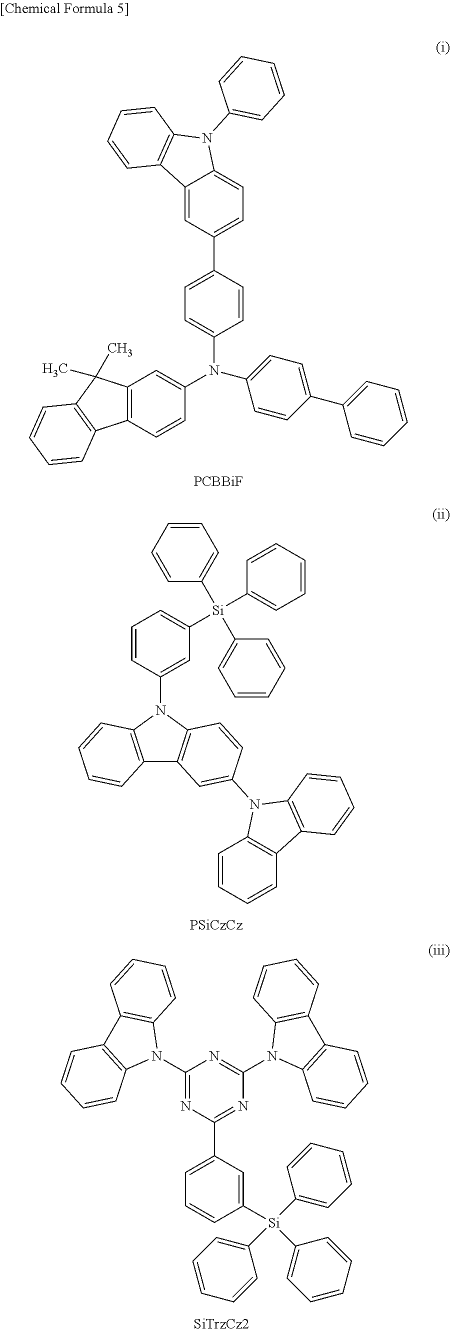

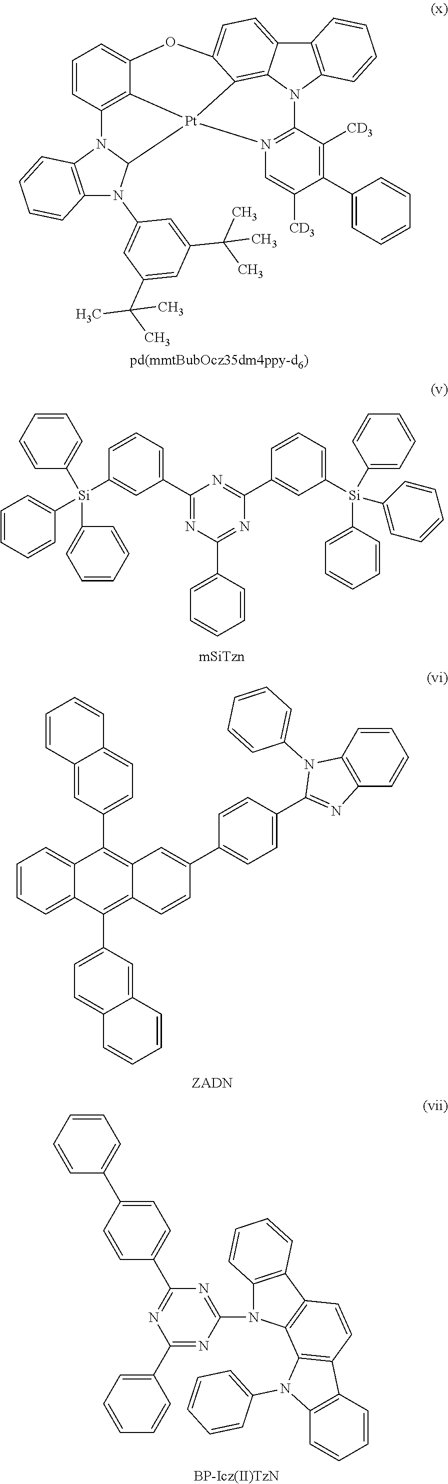

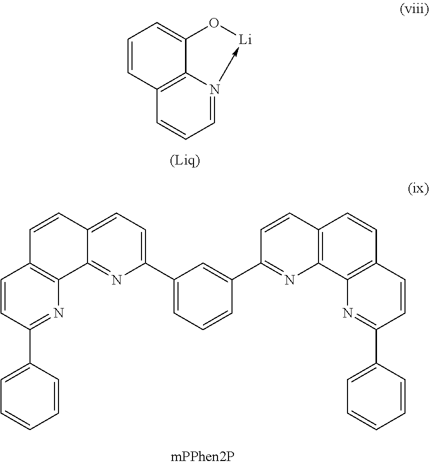

### (Fabrication Method of Light-Emitting Device 3)

First, indium tin oxide containing silicon oxide (ITSO) was deposited over a glass substrate to a thickness of 55 nm by a sputtering method, so that the first electrode 101 having a size of 2 mm×2 mm was formed. Note that the ITSO serves as an anode.

Then, pretreatment for formation of the light-emitting device over the substrate was performed by washing the substrate surface with water.

After that, the substrate was transferred into a vacuum evaporation apparatus where the internal pressure was reduced to approximately 1×10⁴ Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited over the inorganic insulating film and the first electrode 101 to a thickness of 10 nm by co-evaporation such that the weight ratio of PCBBiF to OCHD-003 was 1:0.03, whereby the hole-injection layer 111 was formed.

Over the hole-injection layer 111, PCBBiF was deposited by evaporation to a thickness of 45 nm and then, 9-[3-(triphenylsilyl)phenyl]-3,9′-bi-9H-carbazole (abbreviation: PSiCzCz) was deposited by evaporation to a thickness of 5 nm, whereby the hole-transport layer 112 was formed. Note that PSiCzCz is an organic compound having a π-electron rich heteroaromatic ring, and the PSiCzCz layer functions also as an electron-blocking layer.

Next, over the hole-transport layer 112, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, and (2-{3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-N]carbazole-2,1-diyl-κC)platinum(II) (abbreviation: Pt(mmtBubOcz35dm4ppy-d₆)) represented by Structural Formula (x) above were deposited by co-evaporation to a thickness of 40 nm such that the weight ratio of SiTrzCz2 to PSiCzCz to Pt(mmtBubOcz35dm4ppy-d₆) was 0.35:0.53:0.12, whereby the light-emitting layer 113 was formed. Note that Pt(mmtBubOcz35dm4ppy-d₆) is an organometallic complex that emits blue phosphorescent light (whose emission spectrum has a peak wavelength greater than or equal to 450 nm and less than or equal to 520 nm). SiTrzCz2 is an organic compound having a π-electron deficient heteroaromatic ring, and PSiCzCz is an organic compound having a π-electron rich heteroaromatic ring.

Then, 2-phenyl-4,6-bis[3-(triphenylsilyl)phenyl]-1,3,5-triazine (abbreviation: mSiTrz) represented by Structural Formula (v) above was deposited by evaporation to a thickness of 5 nm, whereby the first electron-transport layer was formed. After that, 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn) represented by Structural Formula (vii) above and 8-quinolinolato-lithium (abbreviation: Liq) represented by Structural Formula (viii) above were deposited by co-evaporation to a thickness of 30 nm such that the weight ratio of BP-Icz(II)Tzn to Liq was 1:4, whereby the second electron-transport layer was formed. Note that mSiTrz and BP-Icz(II)Tzn are organic compounds each having a π-electron deficient heteroaromatic ring, Liq is an organometallic complex including an alkali metal, and the first electron-transport layer functions also as a hole-blocking layer.

After the electron-transport layers were formed, lithium fluoride (abbreviation: LiF) was deposited by evaporation to a thickness of 1 nm to form the electron-injection layer 115, and then aluminum (abbreviation: Al) was deposited by evaporation to a thickness of 200 nm to form the second electrode 102 (cathode).

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under atmospheric pressure for one hour. In this manner, the light-emitting device 3 was fabricated.

### (Fabrication Method of Comparative Light-Emitting Device 3)

The comparative light-emitting device 3 was fabricated in the same manner as the light-emitting device 3 except that the second electron-transport layer in the comparative light-emitting device 3 was formed using 2,2′-(1,3-phenylene)bis(9-phenyl-1,10-phenanthroline) (abbreviation: mPPhen2P) represented by Structural Formula (ix) above.

Device structures of the light-emitting device 3 and the comparative light-emitting device 3 are shown in Table 10.

TABLE 10

| | Thickness | | Comparative light-emitting |
|---|---|---|---|
| | (nm) | Light-emitting device 3 | device 3 |
| Second electrode | 200 | Al | |
| Electron-injection layer | 1 | LiF | |
| Electron-transport layer | 30 | BP-Icz(II)Tzn:Liq (1:4) | mPPhen2P |

| | | |
|---|---|---|
| | 5 | mSiTrz |
| Light-emitting layer | 40 | SiTrzCz2:PSiCzCz:Pt(mmtBubOcz35dm4ppy-d₆) |
| | | (0.35:0.53:0.12) |
| Hole-transport layer | 5 | PSiCzCz |
| | 45 | PCBBiF |
| Hole-injection layer | 10 | PCBBiF:OCHD-003 (1:0.03) |
| First electrode | 55 | ITSO |

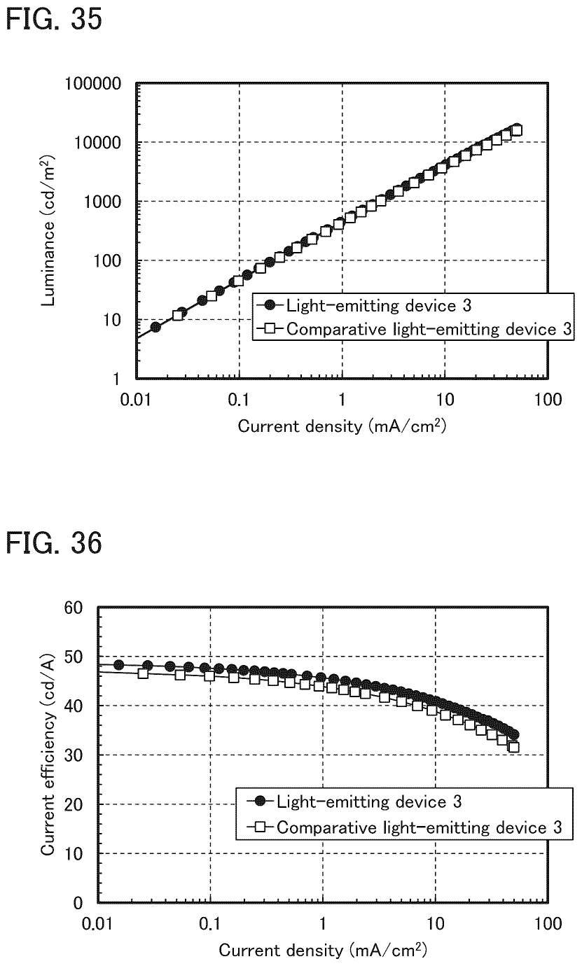

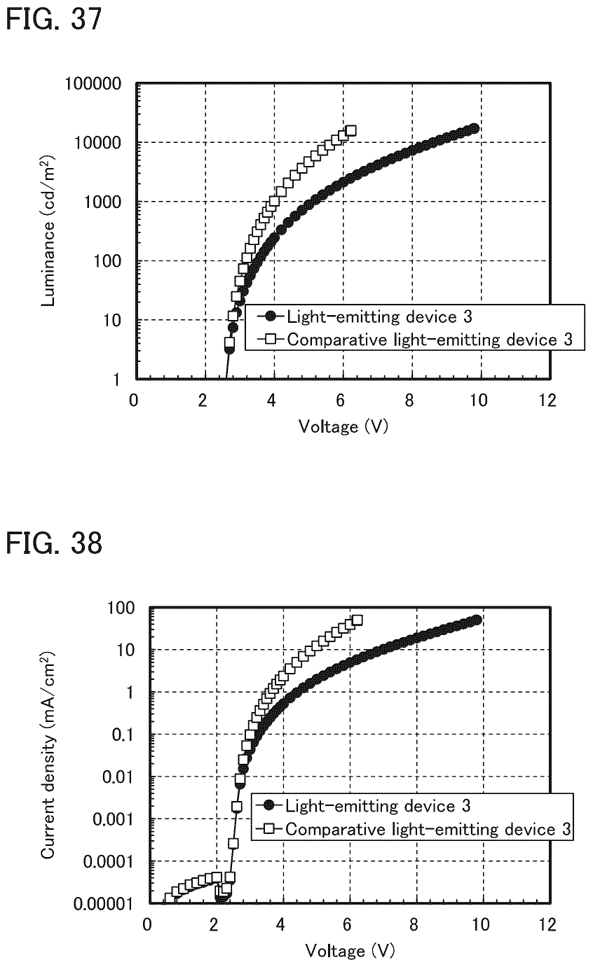

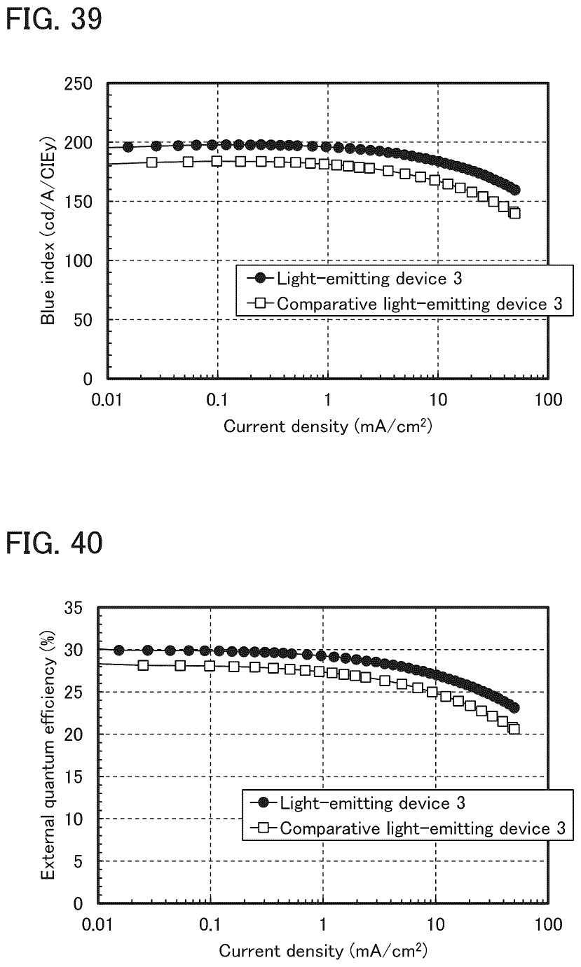

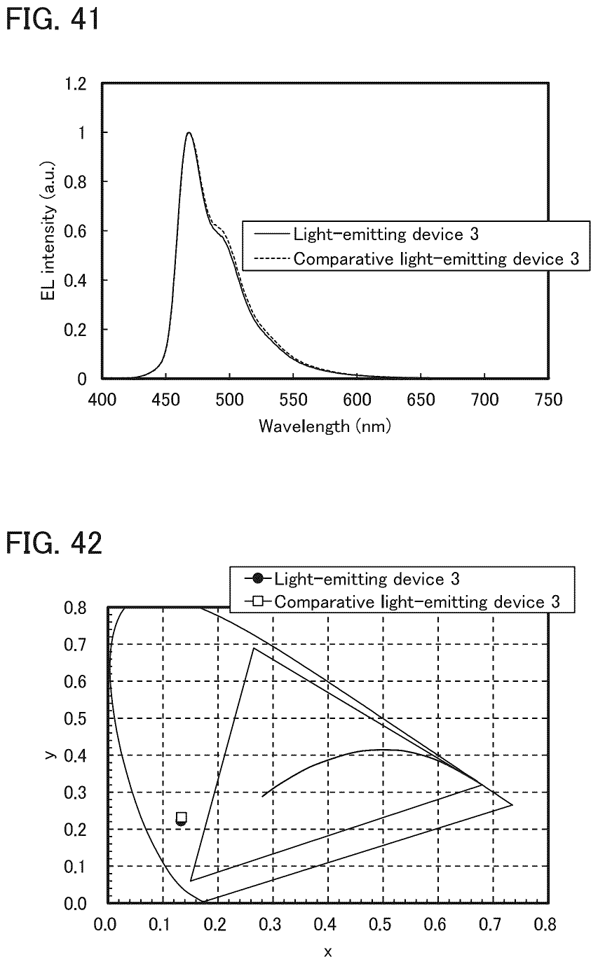

FIG. 35 shows the luminance-current density characteristics of the light-emitting device 3 and the comparative light-emitting device 3. FIG. 36 shows the current efficiency-current density characteristics thereof. FIG. 37 shows the luminance-voltage characteristics thereof. FIG. 38 shows the current density-voltage characteristics thereof. FIG. 39 shows the blue index-current density characteristics thereof. FIG. 40 shows the external quantum efficiency-current density characteristics thereof. FIG. 41 shows the electroluminescence spectra thereof. FIG. 42 shows the CIE chromaticity diagram thereof. Table 11 shows the main characteristics of the light-emitting devices at a current density of 10 mA/cm². The luminance, CIE chromaticity, and electroluminescence spectra were measured at normal temperature with a spectroradiometer (SR-UL1R produced by TOPCON TECHNOHOUSE CORPORATION). The external quantum efficiency was calculated from the measured luminance and emission spectrum, on the assumption that the light-emitting device had Lambertian light-distribution characteristics.

TABLE 11

| | | | | | | | | External |
|---|---|---|---|---|---|---|---|---|
| | | | Chroma- | Chroma- | Current | BI | Power | quantum |
| | Voltage | Luminance | ticity | ticity | efficiency | (cd/A/ | efficiency | efficiency |
| | (V) | (cd/m²) | x | y | (cd/A) | CIEy) | (lm/W) | (%) |
| Light-emitting | 6.98 | 4090 | 0.133 | 0.222 | 40.9 | 184 | 18.4 | 27.0 |
| device 3 | | | | | | | | |
| Comparative | 4.85 | 3880 | 0.134 | 0.232 | 38.8 | 167 | 25.2 | 24.9 |
| light-emitting | | | | | | | | |
| device 3 | | | | | | | | |

The above results reveal that the light-emitting device 3 and the comparative light-emitting device 3 both have favorable characteristics. In addition, the light-emitting device 3 has particularly high current efficiency and external quantum efficiency.

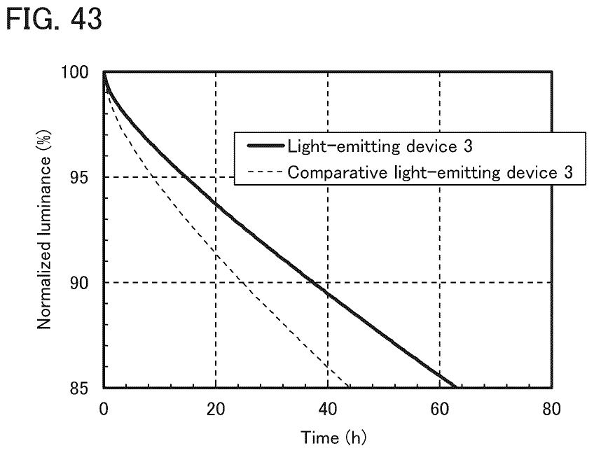

FIG. 43 shows the time dependence of normalized luminances of the light-emitting device 3 and the comparative light-emitting device 3 driven at a current density of 10 mA/cm². Note that the time dependence of normalized luminances is shown assuming the initial luminances to be 100%.

FIG. 43 reveals that the light-emitting device 3 has high reliability with a smaller decrease in luminance over driving time than that of the comparative light-emitting device 3.

FIG. 44 shows the emission spectra (PL spectra) of a film of SiTrzCz2, a film of PSiCzCz, and a mixed film of SiTrzCz2 and PSiCzCz with a weight ratio of 1:1. Note that the emission spectra were measured at room temperature using sample films each deposited by evaporation to a thickness of 50 nm over a quartz substrate. A fluorescence spectrophotometer (FP-8600 manufactured by JASCO Corporation) was used for the measurement. The wavelength of excitation light was set to 330 nm (for the film of SiTrzCz2), 310 nm (for the film of PSiCzCz), and 355 nm (for the mixed film of SiTrzCz2 and PSiCzCz). As shown in FIG. 44, the emission spectrum of the mixed film is positioned on the longer wavelength side than the emission spectra of the films of the single materials, indicating that SiTrzCz2 and PSiCzCz form an exciplex. In other words, a combination of SiTrzCz2 and PSiCzCz forms an exciplex.

Table 12 shows the GSP_Slopes of evaporated films of the organic compound having a π-electron deficient heteroaromatic ring which was used for the first electron-transport layers of the light-emitting device 3 and the comparative light-emitting device 3, the organic compounds each having a π-electron deficient heteroaromatic ring which were used for the second electron-transport layers thereof, the organic compound having a π-electron rich heteroaromatic ring or an aromatic amine which was used for the hole-transport layers thereof, and the host materials used for the light-emitting layers thereof. Note that the GSP_Slopes in Table 12 were measured by the method described in Embodiment 1.

TABLE 12

| Abbreviation of material | GSP_Slope |
|---|---|
| of evaporated film | (mV/nm) |
| mSiTrz | 10.3 |
| BP-Icz(II)Tzn | 92.1 |
| mPPhen2P | 1.50 |
| SiTrzCz2 | 22.4 |
| PSiCzCz | 34.7 |

The above results reveal that, in the light-emitting device 3, the GSP_Slope of the film of the organic compound having a π-electron deficient heteroaromatic ring in the second electron-transport layer is larger than the GSP_Slope of the film of the organic compound having a π-electron deficient heteroaromatic ring in the first electron-transport layer.

Meanwhile, in the comparative light-emitting device 3, the GSP_Slope of the film of the organic compound having a π-electron deficient heteroaromatic ring in the second electron-transport layer is smaller than the GSP_Slope of the film of the organic compound having a π-electron deficient heteroaromatic ring in the first electron-transport layer.

Accordingly, electron injection into the second electron-transport layer is further inhibited in the light-emitting device 3. In the light-emitting layer of the general blue phosphorescent device, the blue phosphorescent light-emitting substance, whose HOMO level and LUMO level are both higher than those of the host material, traps holes but not electrons; thus, the recombination region tends to deviate to the anode side. In the light-emitting device of one embodiment of the present invention, electron injection into the second electron-transport layer is inhibited owing to the above-described structure; thus, the recombination region that tends to deviate to the anode side can be expanded, so that degradation of the hole-transport layer functioning as an electron-blocking layer can be reduced. This improves the reliability of the light-emitting device 3. Note that PSiCzCz used as the host material in the light-emitting layer in this example has a HOMO level of −5.7 eV and a LUMO level of −2.06 eV; SiTrzCz2 used as the host material in the light-emitting layer in this example has a HOMO level lower than that of PSiCzCz and a LUMO level of −2.98 eV; and Pt(mmtBubOcz35dm4ppy-d₆) used as the blue phosphorescent light-emitting substance has a HOMO level of −5.50 eV and a LUMO level of −2.47 eV and thus traps holes but not electrons as described above.

The values of the HOMO levels and the LUMO levels were obtained through a cyclic voltammetry (CV) measurement. The CV measurement was performed in a manner similar to that described in Example 2.

In the light-emitting device 3, the second electron-transport layer contains Liq, which is a metal complex including an alkali metal, in addition to the organic compound having a π-electron deficient heteroaromatic ring. When the weight ratio of the organic compound having a π-electron deficient heteroaromatic ring to Liq in the second electron-transport layer of the light-emitting device 3 is x:y, a value of (x+y)/x times the GSP_Slope of the film of the organic compound having a π-electron deficient heteroaromatic ring in the first electron-transport layer is 51.5 (mV/nm). The GSP_Slope of the film of the organic compound having a π-electron deficient heteroaromatic ring in the second electron-transport layer is larger than (x+y)/x times the GSP_Slope of the film of the organic compound having a π-electron deficient heteroaromatic ring in the first electron-transport layer in the light-emitting device 3.

As described above, when the weight ratio of the organic compound having a π-electron deficient heteroaromatic ring to Liq in the second electron-transport layer is x:y, the GSP_Slope of the film of the organic compound having a π-electron deficient heteroaromatic ring in the second electron-transport layer is larger than (x+y)/x times the GSP_Slope of the film of the organic compound having a π-electron deficient heteroaromatic ring in the first electron-transport layer, so that the light-emitting device can have high reliability.

Note that in the above light-emitting device, the GSP_Slope of the film of each of the host materials (SiTrzCz2 and PSiCzCz) is larger than the GSP_Slope of the film of the first organic compound. The GSP_Slope of the light-emitting layer is larger than the GSP_Slope of the first electron-transport layer.

With this structure, a positive interface charge can be provided at the interface between the light-emitting layer and the first electron-transport layer; thus, electrons are injected smoothly from the second electron-transport layer into the first electron-transport layer in the above light-emitting device. Accordingly, the light-emitting device 3 can have favorable characteristics without causing a significant increase in driving voltage even when electron injection into the second electron-transport layer is inhibited.

Furthermore, BP-Icz(II)Tzn, which is the organic compound having a π-electron deficient heteroaromatic ring in the second electron-transport layer of the light-emitting device 3, has a larger GSP_Slope than the host materials (SiTrzCz2 and PSiCzCz) in a film state. In addition, the GSP_Slope of the second electron-transport layer is larger than the GSP_Slope of the light-emitting layer.

Accordingly, in the light-emitting device 3, the charge at the interface between the first electron-transport layer and the second electron-transport layer is negative and smaller than the charge at the interface between the light-emitting layer and the first electron-transport layer. This inhibits electron injection from the second electrode or the electron-injection layer into the second electron-transport layer. It also promotes hole injection into the light-emitting layer. As a result, the recombination region that normally tends to deviate to the anode side in the light-emitting layer of the blue phosphorescent device can be expanded, so that degradation of the hole-transport layer functioning as an electron-blocking layer can be further reduced.

As described above, the light-emitting device of one embodiment of the present invention can have high reliability and favorable characteristics.

This application is based on Japanese Patent Application Serial No. 2024-196216 filed with Japan Patent Office on Nov. 8, 2024 and Japanese Patent Application Serial No. 2025-076742 filed with Japan Patent Office on May 2, 2025, the entire contents of which are hereby incorporated by reference.

What is claimed is:

1. A light-emitting device comprising:
a first electrode over an insulating surface;
a second electrode facing the first electrode; and
an EL layer between the first electrode and the second electrode,
wherein the EL layer comprises a light-emitting layer, a hole-transport layer, a first electron-transport layer, and a second electron-transport layer,
wherein the first electron-transport layer is between the light-emitting layer and the second electron-transport layer,
wherein the second electron-transport layer is between the first electron-transport layer and the second electrode,
wherein the light-emitting layer is between the hole-transport layer and the first electron-transport layer,
wherein a GSP_Slope (mV/nm) of the second electron-transport layer is larger than a GSP_Slope (mV/nm) of the first electron-transport layer, and
wherein the GSP_Slope (mV/nm) is represented by ΔV/Δd where ΔV (mV) is an amount of change in surface potential and Δd (nm) is an amount of change in thickness.

2. A light-emitting device comprising:
a first electrode over an insulating surface;
a second electrode facing the first electrode; and
an EL layer between the first electrode and the second electrode,
wherein the EL layer comprises a light-emitting layer, a hole-transport layer, a first electron-transport layer, and a second electron-transport layer,
wherein the first electron-transport layer is between the light-emitting layer and the second electron-transport layer,
wherein the second electron-transport layer is between the first electron-transport layer and the second electrode,
wherein the light-emitting layer is between the hole-transport layer and the first electron-transport layer,
wherein the first electron-transport layer comprises a first organic compound,
wherein the second electron-transport layer comprises a second organic compound,
wherein the first organic compound and the second organic compound each independently comprise a π-electron deficient heteroaromatic ring,
wherein a GSP_Slope (mV/nm) of an evaporated film of the second organic compound is larger than a GSP_Slope (mV/nm) of an evaporated film of the first organic compound, and
wherein the GSP_Slope (mV/nm) is represented by ΔV/Δd where ΔV (mV) is an amount of change in surface potential and Δd (nm) is an amount of change in thickness.

3. The light-emitting device according to claim 2,
wherein the second electron-transport layer further comprises a first substance.

4. The light-emitting device according to claim 3,
wherein, in a case where a mixing ratio of the second organic compound to the first substance in the second electron-transport layer is x:y, the GSP_Slope (mV/nm) of the evaporated film of the second organic compound is larger than (x+y)/x times the GSP_Slope (mV/nm) of the evaporated film of the first organic compound.

5. The light-emitting device according to claim 4, wherein y is greater than or equal to x.

6. The light-emitting device according to claim 1, wherein the light-emitting layer comprises a substance which emits phosphorescent light.

7. The light-emitting device according to claim 1,
wherein a GSP_Slope (mV/nm) of the light-emitting layer is larger than the GSP_Slope (mV/nm) of the first electron-transport layer.

8. The light-emitting device according to claim 7, wherein the GSP_Slope (mV/nm) of the light-emitting layer is larger than a GSP_Slope (mV/nm) of the hole-transport layer.

9. The light-emitting device according to claim 2,
wherein the light-emitting layer comprises a host material and a light-emitting substance, and
wherein a GSP_Slope (mV/nm) of an evaporated film of the host material is larger than the GSP_Slope (mV/nm) of the evaporated film of the first organic compound.

10. The light-emitting device according to claim 9, wherein the GSP_Slope (mV/nm) of the evaporated film of the second organic compound is larger than the GSP_Slope (mV/nm) of the evaporated film of the host material.

11. The light-emitting device according to claim 9,
wherein the hole-transport layer comprises a third organic compound, and
wherein a GSP_Slope (mV/nm) of the light-emitting layer is larger than or equal to a GSP_Slope (mV/nm) of an evaporated film of the third organic compound.

12. The light-emitting device according to claim 9,
wherein the hole-transport layer comprises a third organic compound, and
wherein the GSP_Slope (mV/nm) of the evaporated film of the host material is larger than or equal to a GSP_Slope (mV/nm) of an evaporated film of the third organic compound.

13. The light-emitting device according to claim 9,
wherein the host material comprises a first material and a second material, and
wherein the first material and the second material are a combination of organic compounds that form an exciplex.

14. The light-emitting device according to claim 13,
wherein the first material is an organic compound comprising a π-electron deficient heteroaromatic ring, and
wherein the second material is an organic compound comprising a π-electron rich heteroaromatic ring or an aromatic amine.

15. The light-emitting device according to claim 3, wherein the first substance is a metal complex.

16. The light-emitting device according to claim 15, wherein the metal complex is an organic complex comprising an alkali metal.

17. The light-emitting device according to claim 6, wherein a peak wavelength of an emission spectrum of the substance which emits phosphorescent light is greater than or equal to 450 nm and less than or equal to 520 nm.

18. The light-emitting device according to claim 9, wherein a peak wavelength of an emission spectrum of the light-emitting substance is greater than or equal to 450 nm and less than or equal to 520 nm.

19. The light-emitting device according to claim 2, wherein the light-emitting layer comprises a substance which emits phosphorescent light.

20. The light-emitting device according to claim 19, wherein a peak wavelength of an emission spectrum of the substance which emits phosphorescent light is greater than or equal to 450 nm and less than or equal to 520 nm.
